(19) United States
(12) Patent Application Publication
(10) Pub. No.: US 2025/0357314 A1
(43) Pub. Date: Nov. 20, 2025

(54) MEMORY DEVICE INCLUDING CANTILEVERED WORD LINES WITH TAB PORTIONS AND METHODS FOR FORMING THE SAME

(71) Applicant: SANDISK TECHNOLOGIES LLC, ADDISON, TX (US)

(72) Inventors: Airi YAMATE, Yokkaichi (JP); Ryousuke ITOU, Yokkaichi (JP); Yuki FUKUSHIGE, Yokkaichi (JP); Tomohiro ASANO, Nagoya (JP); Youko FURIHATA, Yokkaichi (JP)

(21) Appl. No.: 18/664,861

(22) Filed: May 15, 2024

(51) Int. Cl. H01L 23/522; G11C 16/04; H01L 23/528; H10B 43/10; H10B 43/27; H10B 43/35

(52) U.S. Cl. CPC H01L 23/5226; G11C 16/0483; H01L 23/528; H01L 23/5283; H10B 43/10; H10B 43/27; H10B 43/35

(57) ABSTRACT

A memory device includes an alternating stack of insulating layers and electrically conductive layers that alternate along a vertical direction, memory openings vertically extending through the alternating stack in a memory array region, memory opening fill structures located in the memory openings and including a respective vertical stack of memory elements and a respective vertical semiconductor channel, and layer contact via structures contacting the electrically conductive layers. Each electrically conductive layer within a subset of the electrically conductive layers includes a respective tab portion that laterally protrudes away from the memory array region relative to a respective underlying vertically-neighboring electrically conductive layer and relative to a respective overlying vertically-neighboring electrically conductive layer, and a subset of the layer contact via structures contacts a top surface of a respective one of the tab portions.

### FIELD

The present disclosure relates generally to the field of semiconductor devices, and particularly to a memory device including cantilevered word lines with tab portions for via contacts and methods for forming the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device includes an alternating stack of insulating layers and electrically conductive layers that alternate along a vertical direction; memory openings vertically extending through the alternating stack in a memory array region; memory opening fill structures located in the memory openings and including a respective vertical stack of memory elements and a respective vertical semiconductor channel; and layer contact via structures contacting the electrically conductive layers. Each electrically conductive layer within a subset of the electrically conductive layers includes a respective tab portion that laterally protrudes away from the memory array region relative to a respective underlying vertically-neighboring electrically conductive layer and relative to a respective overlying vertically-neighboring electrically conductive layer; and a subset of the layer contact via structures contacts a top surface of a respective one of the tab portions.

According to another aspect of the present disclosure, a method of forming a memory device is provided. The method comprises: forming an alternating stack of insulating layers and sacrificial material layers over a substrate; forming stepped surfaces by patterning the alternating stack, wherein the stepped surfaces comprise horizontally-extending surfaces and vertically-extending surfaces; forming etch-stop material portions on the vertically-extending surfaces, wherein first vertically-extending surface segments of the vertically extending surfaces are laterally covered by the etch-stop material portions and second vertically-extending surface segments of the vertically-extending surfaces are not laterally covered by the etch-stop material portions; isotropically recessing portions of the sacrificial material layers having sidewalls at the second vertically-extending surface segments without laterally recessing portions of the sacrificial material layers having sidewalls at the first vertically-extending surface segments, such that fin cavities are formed in volumes from which a material of the sacrificial material layers is removed; forming a dielectric material portion over the stepped surfaces, wherein the finned dielectric material portion comprises laterally-extending dielectric fins that fill the fin cavities; forming memory openings through the alternating stack; forming memory opening fill structures in the memory openings, wherein each of the memory opening fill structures comprises a respective vertical stack of memory elements and a vertical semiconductor channel; and replacing the sacrificial material layers with electrically conductive layers.

### BRIEF DESCRIPTION OF THE DRAWINGS

FIG. 1 is a schematic vertical cross-sectional view of an exemplary structure after formation of an alternating stack of insulating layers and sacrificial material layers over a carrier substrate according to an embodiment of the present disclosure.

FIG. 2A is a schematic vertical cross-sectional view of the exemplary structure after formation of stepped surfaces according to an embodiment of the present disclosure.

FIG. 2B is a top-down view of the exemplary structure of FIG. 2A. The hinged vertical plane A-A′ is the cut plane of the vertical cross-sectional view of FIG. 2A.

FIG. 2C is a vertical cross-sectional view of the exemplary structure along the vertical plane C-C′ of FIG. 2B.

FIG. 2D is a vertical cross-sectional view of the exemplary structure along the vertical plane D-D′ of FIG. 2B.

FIGS. 3A-3E are sequential vertical cross-sectional views of a set of stepped surfaces during formation of finned cavities according to an embodiment of the present disclosure.

FIG. 3F is a vertical cross-sectional view of a set of stepped surfaces in an alternative configuration of the exemplary structure after removal of etch-stop material portions according to an embodiment of the present disclosure.

FIG. 4 is a perspective view of a region of the stepped surfaces in the alternative configuration of the exemplary structure of FIG. 3F according to an embodiment of the present disclosure.

FIG. 5A is a schematic vertical cross-sectional view of the exemplary structure after formation of a finned dielectric material portion according to an embodiment of the present disclosure.

FIG. 5B is a top-down view of the exemplary structure of FIG. 5A. The hinged vertical plane A-A′ is the cut plane of the vertical cross-sectional view of FIG. 5A.

FIG. 5C is a vertical cross-sectional view of the exemplary structure along the vertical plane C-C′ of FIG. 5B.

FIG. 5D is a vertical cross-sectional view of the exemplary structure along the vertical plane D-D′ of FIG. 5B.

FIG. 5E is a vertical cross-sectional view of a region of the exemplary structure of FIGS. 5A-5D.

FIG. 5F is a vertical cross-sectional view of a region of an alternative embodiment of the exemplary structure at a processing step that corresponds to the processing steps of FIGS. 5A-5E.

FIG. 6A is a schematic vertical cross-sectional view of the exemplary structure after formation of memory openings and support openings according to an embodiment of the present disclosure.

FIG. 6B is a top-down view of the exemplary structure of FIG. 6A. The hinged vertical plane A-A′ is the cut plane of the vertical cross-sectional view of FIG. 6A.

FIG. 6C is a vertical cross-sectional view of the exemplary structure along the vertical plane C-C′ of FIG. 6B.

FIG. 6D is a vertical cross-sectional view of the exemplary structure along the vertical plane D-D′ of FIG. 6B.

FIG. 7 is a schematic vertical cross-sectional view of the exemplary structure after formation of sacrificial opening fill structures according to an embodiment of the present disclosure.

FIG. 8 is a vertical cross-sectional view of the exemplary structure after formation of support pillar structures according to an embodiment of the present disclosure.

FIG. 9 is a schematic vertical cross-sectional view of the exemplary structure after removal of sacrificial memory opening fill structures according to an embodiment of the present disclosure.

FIGS. 10A-10F are sequential vertical cross-sectional views of a memory opening during formation of a memory opening fill structure according to an embodiments of the present disclosure.

FIG. 11A is a schematic vertical cross-sectional view of the exemplary structure after formation of memory opening fill structures according to an embodiment of the present disclosure.

FIG. 11B is a top-down view of the exemplary structure of FIG. 11A. The hinged vertical plane A-A is the cut plane of the vertical cross-sectional view of FIG. 11A.

FIG. 11C is a vertical cross-sectional view of the exemplary structure along the vertical plane C-C′ of FIG. 11B.

FIG. 11D is a vertical cross-sectional view of the exemplary structure along the vertical plane D-D′ of FIG. 11B.

FIG. 12A is a vertical cross-sectional view of the exemplary structure after formation of lateral isolation trenches according to an embodiment of the present disclosure.

FIG. 12B is a top-down view of the exemplary structure of FIG. 12A. The hinged vertical plane A-A is the cut plane of the vertical cross-sectional view of FIG. 12A.

FIG. 12C is a vertical cross-sectional view of the exemplary structure along the vertical plane C-C′ of FIG. 12B.

FIG. 12D is a vertical cross-sectional view of the exemplary structure along the vertical plane D-D′ of FIG. 12B.

FIG. 13 is a vertical cross-sectional view of the exemplary structure after formation of laterally-extending cavities according to an embodiment of the present disclosure.

FIG. 14A is a schematic vertical cross-sectional view of the exemplary structure after formation of electrically conductive layers according to an embodiment of the present disclosure.

FIG. 14B is a top-down view of the exemplary structure of FIG. 14A. The hinged vertical plane A-A is the cut plane of the vertical cross-sectional view of FIG. 14A.

FIG. 14C is a vertical cross-sectional view of the exemplary structure along the vertical plane C-C′ of FIG. 14B.

FIG. 14D is a vertical cross-sectional view of the exemplary structure along the vertical plane D-D′ of FIG. 14B.

FIG. 14E is a vertical cross-sectional view of a region of the exemplary structure of FIGS. 14A-14D.

FIG. 14F is a vertical cross-sectional view of a region of an alternative configuration of the exemplary structure of FIGS. 14A-14D.

FIG. 15 is a vertical cross-sectional view of the exemplary structure after formation of lateral isolation trench fill structures according to an embodiment of the present disclosure.

FIG. 16A is a vertical cross-sectional view of the exemplary structure after formation of layer contact via structures and drain contact via structures according to an embodiment of the present disclosure.

FIG. 16B is a top-down view of the exemplary structure of FIG. 16A. The hinged vertical plane A-A is the cut plane of the vertical cross-sectional view of FIG. 16A.

FIG. 16C is a vertical cross-sectional view of the exemplary structure along the vertical plane C-C′ of FIG. 16B.

FIG. 16D is a vertical cross-sectional view of the exemplary structure along the vertical plane D-D′ of FIG. 16B.

FIG. 17A is a vertical cross-sectional view of an alternative configuration of the exemplary structure after formation of layer contact via structures and drain contact via structures according to an embodiment of the present disclosure.

FIG. 17B is a top-down view of the exemplary structure of FIG. 17A. The hinged vertical plane A-A is the cut plane of the vertical cross-sectional view of FIG. 17A.

FIG. 17C is a vertical cross-sectional view of the exemplary structure along the vertical plane C-C′ of FIG. 17B.

FIG. 17D is a vertical cross-sectional view of the exemplary structure along the vertical plane D-D′ of FIG. 17B.

FIG. 18 is a vertical cross-sectional view of the exemplary structure after formation of a memory die according to an embodiment of the present disclosure.

FIG. 19 is a vertical cross-sectional view of a logic die according to an embodiment of the present disclosure.

FIG. 20 is a vertical cross-sectional view of the exemplary structure after attaching the logic die to the memory die according to an embodiment of the present disclosure.

FIG. 21 is a vertical cross-sectional view of the exemplary structure after removal of the carrier substrate according to an embodiment of the present disclosure.

FIG. 22 is a vertical cross-sectional view of the exemplary structure after formation of a source layer according to the first or the second embodiments of the present disclosure.

FIGS. 23A-23G are sequential vertical cross-sectional views of a set of stepped surfaces during formation of a second exemplary structure of an alternative embodiment of the present disclosure.

### DETAILED DESCRIPTION

As discussed above, the embodiments of the present disclosure are directed to a memory device including cantilevered word lines with tab portions for via contacts and methods for forming the same, the various aspects of which are described below. Embodiments of the disclosure can be employed to form various structures including a multilevel memory structure, non-limiting examples of which include three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or with each other, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1×10⁻⁵ S/m to 1×10⁵ S/m. As used herein, a “semiconductor material” refers to a material having electrical conductivity in the range from 1×10⁻⁵ S/m to 1 S/m in the absence of electrical dopants therein, and is capable of producing a doped material having electrical conductivity in a range from 1 S/m to 1×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1×10⁵ S/m. As used herein, an “insulator material” or a “dielectric material” refers to a material having electrical conductivity less than 1×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1×10⁻⁵ S/m to 1×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

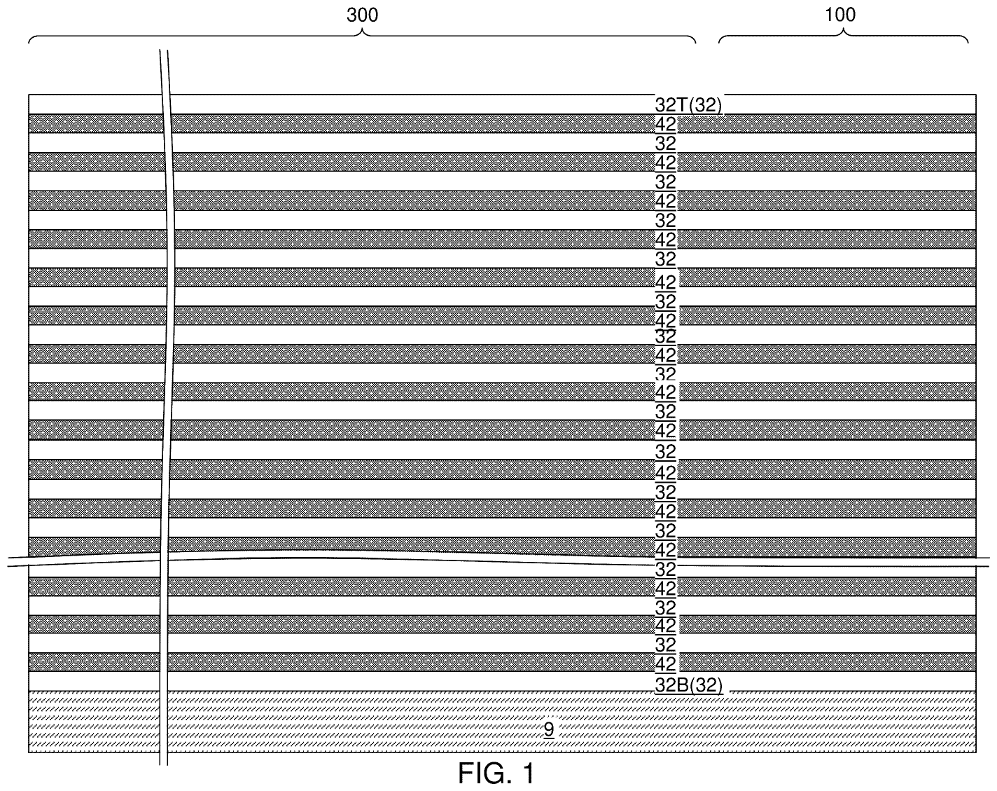

Referring to FIG. 1, an exemplary structure according to an embodiment of the present disclosure is illustrated. The exemplary structure comprises a carrier substrate 9, which may be a semiconductor substrate or a conductive substrate. For example, the carrier substrate 9 may comprise a commercially available silicon wafer. Alternatively, the carrier substrate 9 may comprise any material that may be removed selective the materials of insulating layers 32 and dielectric material portions to be subsequently formed.

An alternating stack of first material layers and second material layers can be formed over the carrier substrate 9. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the carrier substrate 9. The insulating layers 32 comprise an insulating material such as undoped silicate glass or a doped silicate glass, and the sacrificial material layers 42 comprise a sacrificial material such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers.

The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, each of the insulating layers 32 may have a first thickness, and each of the sacrificial material layers 42 may have a second thickness.

The exemplary structure comprises a memory array region 100 in which a three-dimensional array of memory elements is to be subsequently formed, and a contact region 300 in which layer contact via structures contacting word lines are to be subsequently formed. Drain-select-level isolation structures 72 laterally extending along a first horizontal direction hd1 may be formed through a subset of the uppermost sacrificial material layers 42 that will be replaced with drain side select gate electrodes.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

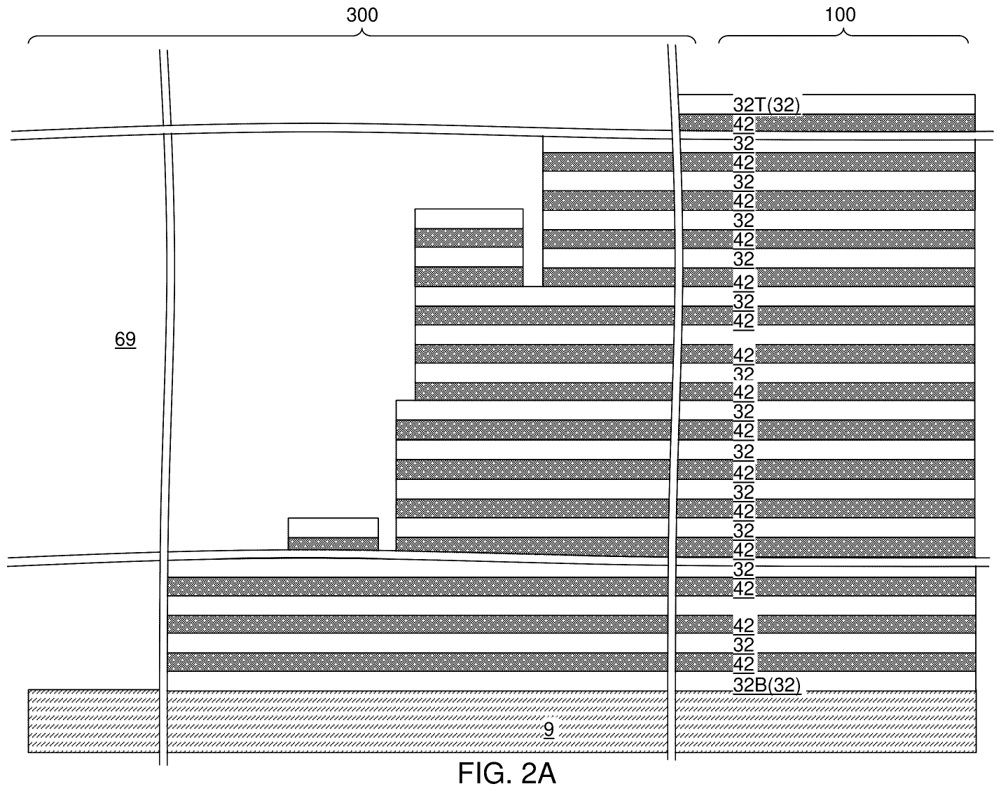

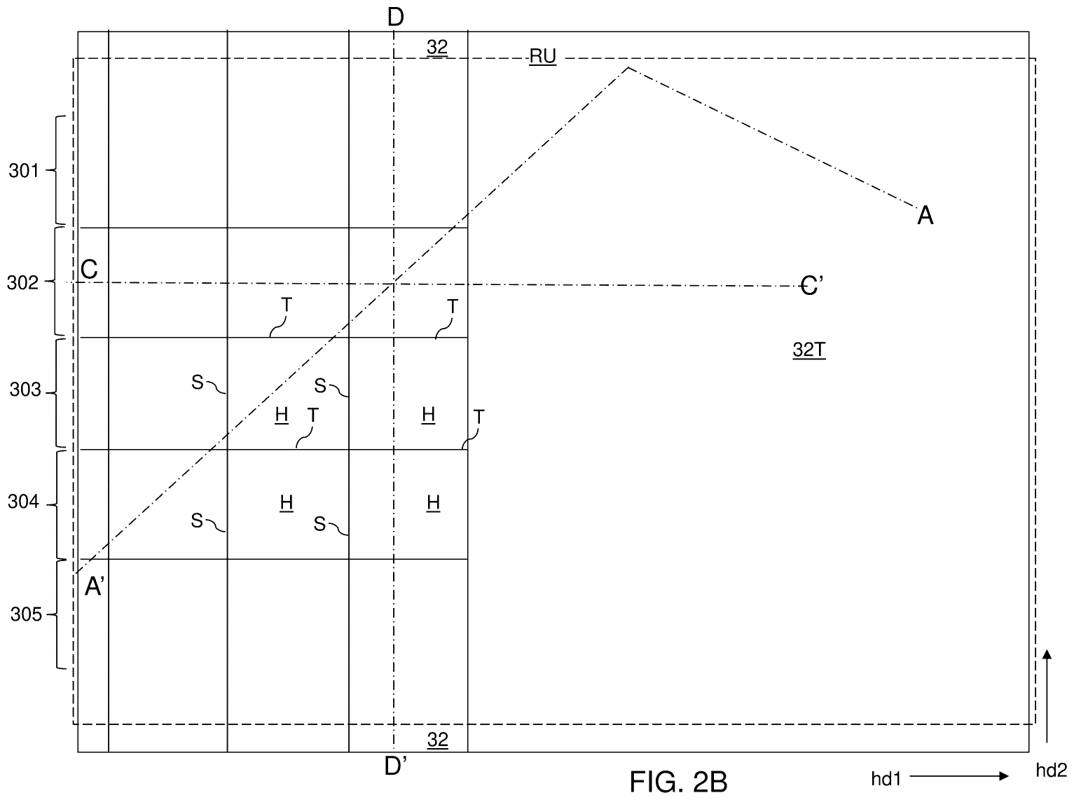

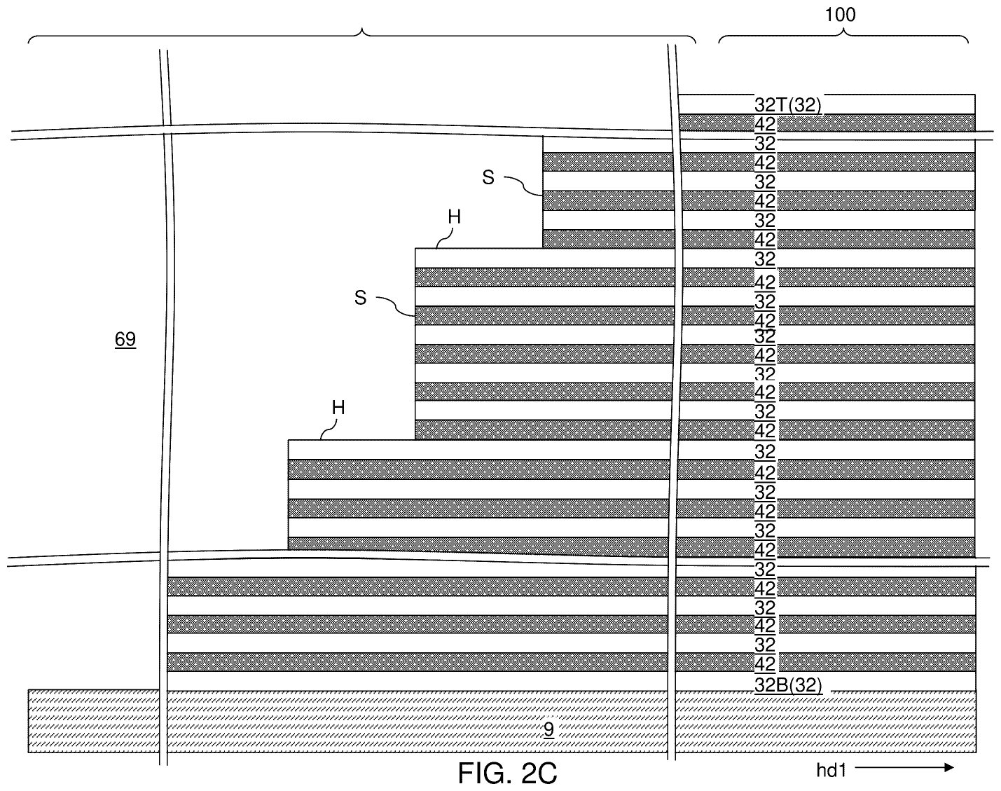

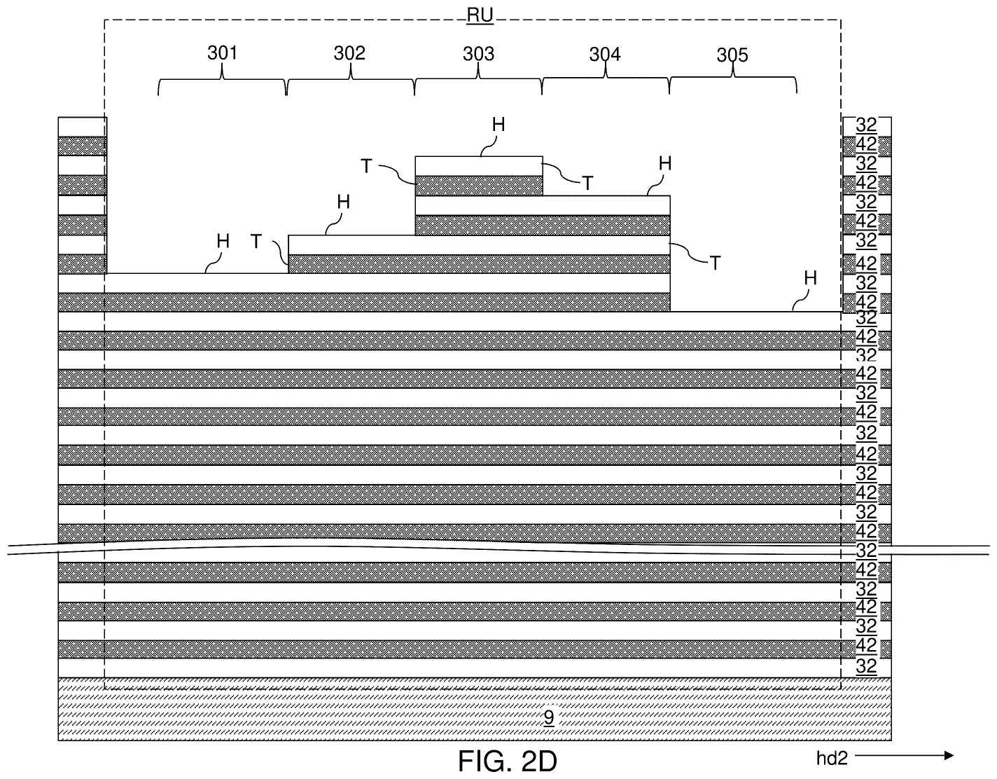

Referring to FIGS. 2A-2D, stepped surfaces can be formed in the contact region 300. As used herein, “stepped surfaces” refer to a set of surfaces that include at least two horizontal surfaces and at least two vertical surfaces such that each horizontal surface is adjoined to a first vertical surface that extends upward from a edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the carrier substrate 9. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

In one embodiment, each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) may continuously extend from a bottommost layer within the alternating stack (32, 42) (such as the bottommost insulating layer 32B) to a topmost layer within the alternating stack (32, 42) (such as the topmost insulating layer 32T).

According to an aspect of the present disclosure, the stepped surfaces can be formed such that multiple staircases (301, 302, 303, 304, 305) are formed in the contact region 300. As used herein, a “staircase” refers to a structure (e.g., 303) including a contiguous combination of vertically-extending surfaces (e.g., first-type vertical steps, S) and horizontally-extending surfaces (H). Each staircase (301, 302, 303, 304, 305) may include a plurality of horizontally-extending surfaces H that laterally extend along a first horizontal direction hd1 and a plurality of vertically-extending surfaces S that connect a respective neighboring pair of horizontally-extending surfaces H. The first horizontal direction hd1 may be the horizontal direction along which the memory array region 100 and the contact region 300 (e.g., word line direction) are laterally spaced from each other. Each staircase (301, 302, 303, 304, 305) may have a respective uniform width along a second horizontal direction (e.g., bit line direction) hd2 that is perpendicular to the first horizontal direction hd1. In one embodiment, each staircase (301, 302, 303, 304, 305) may continuously extend from the carrier substrate 9 to the topmost insulating layer 32T. Vertical steps that are formed in the exemplary structure include first-type vertical steps S that are formed between neighboring horizontally-extending surfaces within a staircase (e.g., 303), and second-type vertical steps T that are formed between neighboring pairs of staircases (e.g., 302 and 303). The neighboring staircases are offset from each other along the second horizontal direction hd2.

A predominant fraction (i.e., greater than 0.5) of all vertically-extending surfaces S of each staircase may have a vertical extent that is an integer M times a sum of the first thickness (i.e., the thickness of each insulating layer 32) and the second thickness (i.e., the thickness of each sacrificial material layer 42). According to an aspect of the present disclosure, the integer M may have a value in a range from 3 to 7, i.e., a value selected from 3, 4, 5, 6, and 7. Thus, the vertically-extending surfaces S include three to seven pairs of adjacent insulating layers 32 and sacrificial material layers 42. In one embodiment, for each staircase (e.g., 303) that is formed in the contact region 300, all vertically-extending surfaces S of the staircase (e.g., 303) except the topmost vertically-extending surface and except the bottommost vertically-extending surface may have a same vertical extent that equals the integer M times the sum of the first thickness (i.e., the thickness of each insulating layer 32) and the second thickness (i.e., the thickness of each sacrificial material layer 42).

Each staircase (e.g., 303) may laterally extend along the first horizontal direction hd1, and may be spaced from other staircases (e.g., 302 and 304) along a second horizontal direction hd2 that is perpendicular to the first horizontal direction hd1. Neighboring staircases that are laterally offset along the second horizontal direction hd2 relative to each other are vertically offset by an integer K times the sum of the first thickness and the second thickness, in which K is a positive integer less than M. Thus, neighboring staircases (e.g., 302 and 303) may be vertically offset by the second-type vertical steps T including one to six pairs of adjacent insulating layers 32 and sacrificial material layers 42. A contiguous group of M staircases (301, 302, 303, 304, 305) can be arranged along the second horizontal direction hd2, and the pattern of the continuous group of M staircases can be repeated along the second horizontal direction hd2. Thus, the contiguous group of M staircases (301, 302, 303, 304, 305) constitutes a repetition unit RU for a pattern that is repeated along the second horizontal direction hd2. In other words, the pattern of the M staircases (301, 302, 303, 304, 305) contained within the repetition unit RU is repeated along the second horizontal direction hd2 as a unit of repetition. In the illustrated example in FIGS. 2A-2D, the integer Mis 5. As discussed above, the integer M may be in a range from 3 to 7.

In one embodiment, vertically-extending surfaces S within a contiguous group of M staircases may be aligned along the first horizontal direction such that M vertically-extending surfaces S from the M staircases are formed within a same vertical plane that is perpendicular to the first horizontal direction hd1 and parallel to the second horizontal direction hd2. A plurality of vertical planes can be laterally spaced apart along the first horizontal direction hd1, and each of the vertical planes may contain a respective set of M vertically-extending surfaces S. In one embodiment, in each vertical cross-sectional view along a vertical plane that is perpendicular to the first horizontal direction hd1, parallel to the second horizontal direction hd2 and passing through horizontally-extending surfaces H of staircases (301, 302, 303, 304, 305) within a contiguous group of M staircases, the horizontally-extending surfaces H of the contiguous group of M staircases may be located at M different heights, as shown in FIG. 2D. The M different heights may be vertically offset by a respective second-type vertical step (i.e., vertical surface) T from each other by integer (e.g., integer K) multiples of the sum of the first thickness (i.e., the thickness of an insulating layer 32) and the second thickness (i.e., the thickness of a sacrificial material layer 42). FIG. 2D illustrates an example of such vertical offsets in case M is 5 and K ranges from 1 to 3.

The staircases can be formed, for example, by performing a first patterning process in which areas of staircases are vertically offset into M different levels along the second horizontal direction hd2, and by performing a second patterning process in which vertical steps S having heights of M times the sum of the first thickness and the second thickness and perpendicular to the first horizontal direction hd1 are formed. During the first patterning process, (M-1) rectangular recess regions can be formed within each repetition unit RU such that each rectangular recess region is recessed by integer multiples of the sum of the first thickness and the second thickness. The integer multiples can include each integer from 1 to (M-1). The (M-1) rectangular recess regions can be formed by performing masked recess etch processes. During each recess etch process, a patterned photoresist layer including a set of rectangular openings can be formed over the first exemplary structure such that the area of the rectangular openings correspond to areas in which the material layers are of the alternating stack (32, 42) are to be etched, and by performing an anisotropic etch process that etches an integer number of pairs of an insulating layer 32 and a sacrificial material layer 42.

During the second patterning process, a trimmable mask layer having an edge that is parallel to the second horizontal direction hd2 can be formed at the location of most distal vertically-extending surfaces of the staircases to be formed. The trimmable mask layer comprise a trimmable masking material, such as a carbon-based masking material that is conducive to controlled isotropic recessing, for example, by ashing. The rate of ashing can be low so that the amount of removed material and the recess distance can be controlled. The trimmable mask layer covers the entirety of the memory array region 100 and areas of the contact region 300 that are proximal to the memory array region 100. The most distal vertically-extending surfaces refer to a subset of the vertically-extending surfaces that is most distal from the memory array region 100. An anisotropic etch process can be performed to vertically recess unmasked portions of the alternating stack (32, 42) by M pairs of insulating layers 32 and sacrificial material layers 42. Thus, unmasked portions of the stepped surfaces of the alternating stack (32, 42) as patterned by the first patterning process are vertically recessed by a vertical recess distance of M times the sum of the first thickness and the second thickness.

Subsequently, the trimmable mask layer can be trimmed such that the edge of the trimmable mask layer that overlies newly-formed vertically-extending surfaces of the alternating stack (32, 42) is laterally shifted toward the memory array region 100 by a trimming distance. The trimming distance can be the same as the width of a set of laterally-extending surfaces to be subsequently formed in the alternating stack (32, 42). An anisotropic etch process can be performed to vertically recess unmasked portions of the alternating stack (32, 42) by M pairs of insulating layers 32 and sacrificial material layers 42. A combination of a trimming step that trims the trimmable mask layer and an anisotropic etch step that vertically recesses unmasked portions of the alternating stack (32, 42) by M pairs of insulating layers 32 and sacrificial material layers 42 can be repeated until the top surface of the carrier substrate 9 is exposed in a peripheral region (not shown) that is more distal from the memory array region 100 than the contact region 300 is from the memory array region 100. The trimmable mask layer can be subsequently removed by performing a final ashing process.

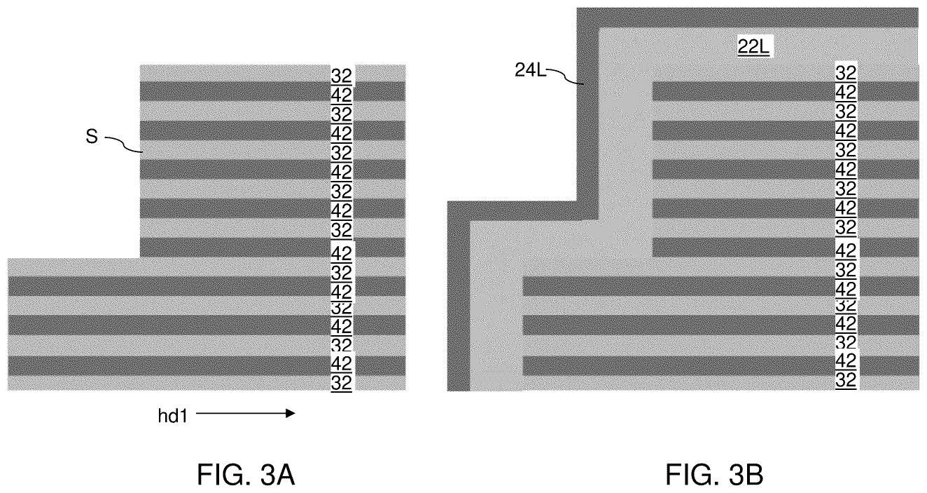

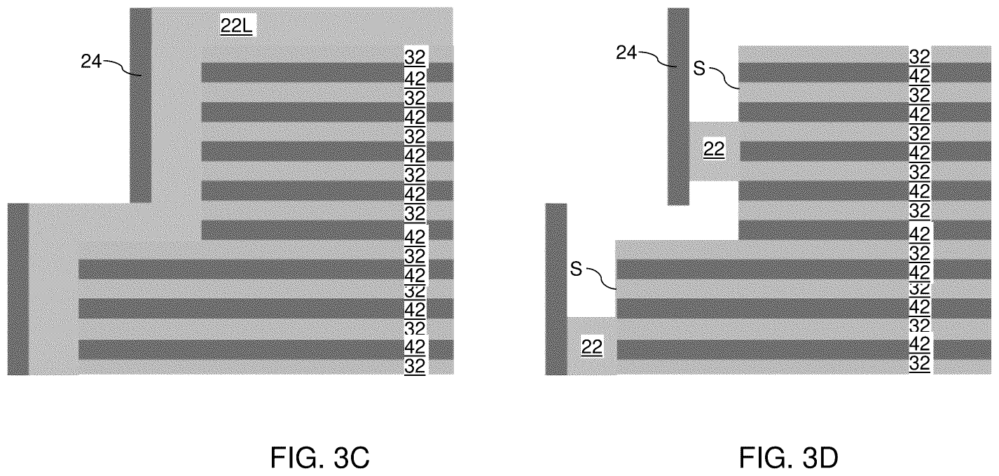

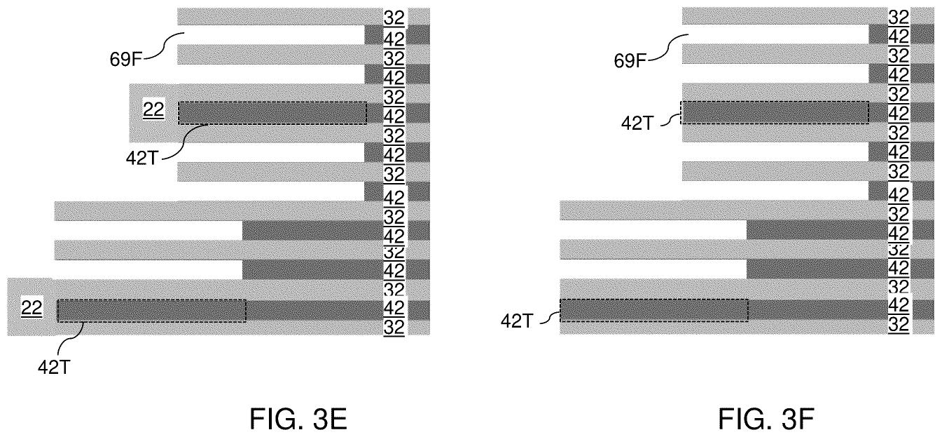

FIGS. 3A-3E are sequential vertical cross-sectional views of a set of stepped surfaces during formation of finned cavities according to an embodiment of the present disclosure.

Referring to FIG. 3A, a region of stepped surfaces S of a staircase region is illustrated in a vertical cross-sectional view along a vertical plane that is parallel to the first horizontal direction hd1 and perpendicular to the second horizontal direction hd2.

Referring to FIG. 3B, an etch-stop material layer 22L can be formed over the stepped surfaces of the alternating stack (32, 42). The etch-stop material layer 22L comprises a material that is different from the materials of the insulating layers 32 and the sacrificial material layers 42. The etch-stop material layer 22L comprises a material that can be employed as an etch-stop material during a subsequent isotropic etch process that is employed to etch the material of the sacrificial material layers 42. For example, the insulating layers 32 may comprise silicon oxide, the sacrificial material layers 42 may comprise silicon nitride, and the etch-stop material layer 22L may comprise a semiconductor material, such as silicon. In one embodiment, the etch-stop material layer 22L may comprise amorphous silicon or polysilicon that is intrinsic (i.e., undoped, e.g., not intentionally doped during a deposition process). Any dopant in an undoped semiconductor material is at a residual (e.g., unavoidable impurity) level. For example, the atomic concentration of electrical dopants in an undoped semiconductor material may be less than 1.0×10¹⁵/cm³, and/or is less than 1.0×10¹⁴/cm³, and/or is less than 1.0×10¹²/cm³. The thickness of the etch-stop material layer 22L can be selected to optimize shapes of etch-stop material portions to be subsequently patterned out of the etch-stop material layer 22L, and may be in a range from 20 nm to 200 nm, although lesser and greater thicknesses may also be employed. The etch-stop material layer 22L can be formed, for example, by low pressure chemical vapor deposition (LPCVD).

A barrier material layer 24L can be subsequently deposited over the etch-stop material layer 22L. The barrier material layer 24L comprises a material that is different from the materials of the insulating layers 32 and the etch-stop material layer 22L. The barrier material layer 24L comprises a material that can function as an etch-stop barrier material during a subsequent isotropic etch process to be employed to etch the material of the etch-stop material layer 22L. In one embodiment, the barrier material layer 24L may comprise a same material as the sacrificial material layers 42. For example, the sacrificial material layers 42 and the barrier material layer 24L may comprise silicon nitride. The thickness of the barrier material layer 24L may be in a range from 20 nm to 100 nm, although lesser and greater thicknesses may also be employed. The thickness of the barrier material layer 24L can be selected to optimize the vertical location of the etch-stop material portions to be subsequently patterned out of the etch-stop material layer 22L, The barrier material layer 24L can be formed, for example, by low pressure chemical vapor deposition (LPCVD).

Referring to FIG. 3C, an anisotropic etch process can be performed to remove horizontally-extending portions of the barrier material layer 24L. The horizontally-extending portions of the barrier material layer 24L can be removed from above horizontally-extending portions of the etch-stop material layer 22L. Remaining vertically-extending portions of the barrier material layer 24L comprise barrier walls 24. Horizontal surfaces of the etch-stop material layer 22L are physically exposed between neighboring pairs of barrier walls 24. Optionally, the exposed horizontal surfaces of the etch-stop material layer 22L may also be removed during the anisotropic etch process.

Referring to FIG. 3D, the etch-stop material layer 22L can be isotropically etched by performing an isotropic etch process. The isotropic etch process has an etch chemistry that etches the material of the etch-stop material layer 22L selective to the materials of the insulating layers 32, the sacrificial material layers 42, and the barrier walls 24. For example, if the etch-stop material layer 22L comprises amorphous silicon, the isotropic etch process may be a wet etch process using hot trimethyl-2 hydroxyethyl ammonium hydroxide (“hot TMY”) or tetramethyl ammonium hydroxide (TMAH). The barrier walls 24 function as geometrical barrier structures for access of the isotropic etchant to the etch-stop material layer 22L.

The isotropic etchant etches the vertical portions of the etch-stop material layer 22L located behind the barrier walls 24 both upwards and downwards (i.e., the upper parts and lower parts of the vertical portions of the etch-stop material layer 22L located behind the barrier walls 24). Remaining portions of the etch-stop material layer 22L comprise etch-stop material portions 22. While vertical cross-sectional shapes of the etch-stop material portions 22 are represented as rectangles, it is understood that top surfaces and the bottom surfaces of the etch-stop material portions 22 may have contoured profiles. The vertical sidewalls of the etch-stop material portions 22 may be straight. According to an aspect of the present disclosure, the isotropic etch process can be timed such that each etch-stop material portion 22 that laterally extends along the second horizontal direction hd2 covers an entirety of a sidewall of one of the sacrificial material layers 42 in each of the vertical steps S, and at least partly covers a sidewall of an overlying insulating layer 32 that overlies the sacrificial material layer 42 and at least partly covers a sidewall of an underlying insulating layer 32. The vertical extent of each etch-stop material portion 22 is limited such that each etch-stop material portion 22 does not fully cover sidewalls of two sacrificial material layers 42. Thus, each etch-stop material portion 22 fully covers a sidewall of a sacrificial material layer 42 that laterally extends along the second horizontal direction, at least partly covers sidewalls of two insulating layers 32 that are in direct contact with the sacrificial material layer 42, and may partly cover, but does not fully cover, sidewalls of an overlying sacrificial material layer 42 and an underlying sacrificial material layer 42 that in contact with the two insulating layers 32.

Thus, the etch-stop material portions 22 are formed on the vertically-extending surfaces S of the stepped surfaces. First vertically-extending surface segments of the vertically extending surfaces S are laterally covered by the etch-stop material portions 22, and second vertically-extending surface segments of the vertically-extending surfaces are not laterally covered by the etch-stop material portions 22. For a vertically-extending surface, i.e., for a vertical step within a staircase region, the first vertically-extending surface segment includes a sidewall of a sacrificial material layer 42, and the second vertically-extending surface segments include at least a portion of a sidewall of an overlying sacrificial material layer 42 and at least a portion of a sidewall of an underlying sacrificial material layer 42. The second vertically-extending surface segments may include an entirety of a sidewall of another overlying sacrificial material layer 42 and/or a sidewall of another underlying sacrificial material layer 42. The second vertically-extending surface segments may include a portion of an overlying insulating layer 32 that contacts the sacrificial material layer 42, and/or may include a portion of an underlying insulating layer 32 that contacts the sacrificial material layer 42. The second vertically-extending surface segments may include a sidewall of another overlying insulating layer 32 and/or a sidewall of another underlying insulating layer 32.

Referring to FIG. 3E, another isotropic etch process can be performed to remove the barrier walls 24 and to isotropically recess portions of the sacrificial material layers 42 that are not masked by the etch-stop material portion 22. For example, if the barrier walls 24 and the sacrificial material layers comprise silicon nitride, then a phosphoric acid may be used as the isotropic etchant to remove the barrier walls 24 and to recess the sacrificial material layers 42. Thus, portions of the sacrificial material layers 42 having sidewalls at the second vertically-extending surface segments are laterally recessed, while portions of the sacrificial material layers 42 having sidewalls at the first vertically-extending surface segments (which are laterally covered by the etch-stop material portions 22) are not laterally recessed. In one embodiment, the lateral recess distance of this isotropic etch process may be on the order of the length of each laterally-extending (i.e., horizontal) surface H within the staircases (301-305). For example, the lateral recess distance may be in a range from 40 nm to 400 nm, such as 80 nm to 200 nm, although lesser and greater lateral recess distances may also be employed. Fin cavities 69F are formed in volumes from which the material of the sacrificial material layers 42 is removed.

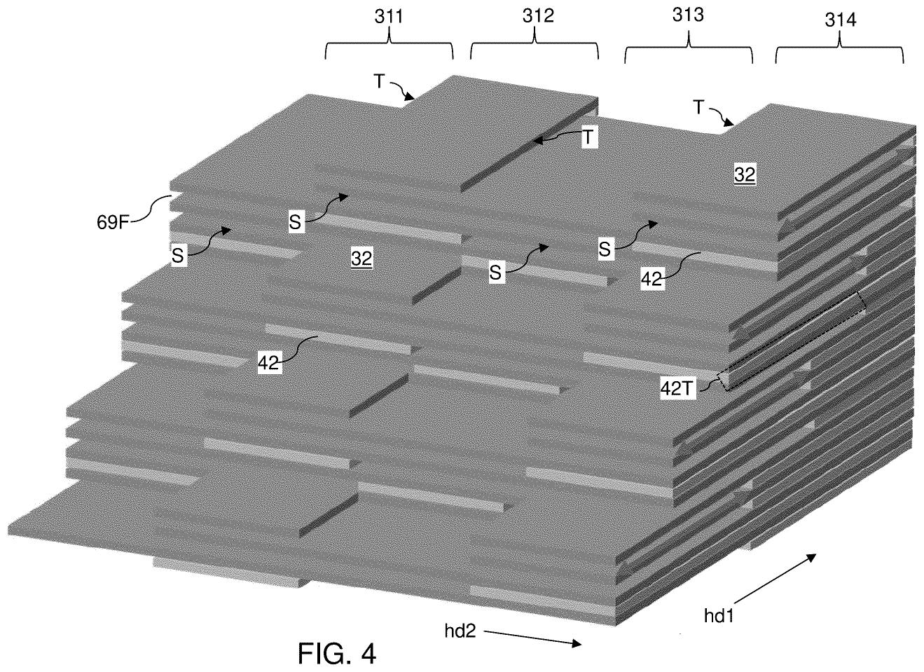

Referring to FIGS. 3F and 4, an alternative configuration of the exemplary structure is illustrated, which can be derived from the exemplary structure of FIG. 3E by performing an additional selective etch process that etches the material of the etch-stop material portions 22 selective to the materials of the insulating layers 32 and the sacrificial material layers 42. If the etch-stop material portions 22 comprise amorphous silicon, the etch process may comprise a wet etch process using hot trimethyl-2 hydroxyethyl ammonium hydroxide (“hot TMY”) or tetramethyl ammonium hydroxide (TMAH). The direction of the arrows in FIG. 4 represent the direction of lateral recessing of the sacrificial material layers 42 at the processing steps described with reference to FIG. 3F. It should be noted that the alternative structure shown in FIG. 4 includes four staircases (311, 312, 312 and 314) (i.e., D=4) instead of five staircases shown in FIGS. 2B and 2D. Furthermore, the vertical surfaces T in FIG. 4 may have a different number of pairs of insulating layers 32 and sacrificial material layers 42 than those shown in FIG. 2D.

Referring collectively to FIGS. 3E, 3F, and 4, the exemplary structure comprises an alternating stack of insulating layers 32 and sacrificial material layers 42. A subset of the sacrificial material layers 42 comprise a respective tab portion 42T that underlies at least one fin cavity 69F and overlies at least another fin cavity 69F. The tab portions 42T of the subset of the sacrificial material layers 42 laterally protrude along the first horizontal direction hd1 and are laterally cantilevered past at least one respective underlying sacrificial material layer 42. The tab portions 42T have a respective tab width that is less than the width of a repetition unit RU along the second horizontal direction hd2.

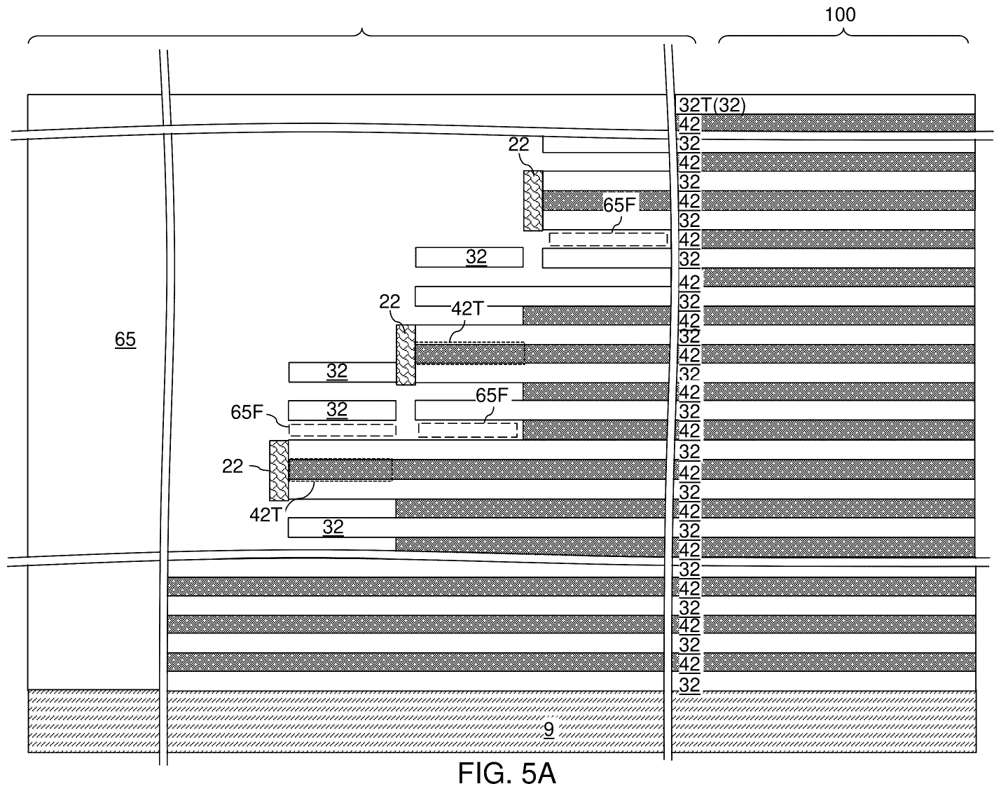

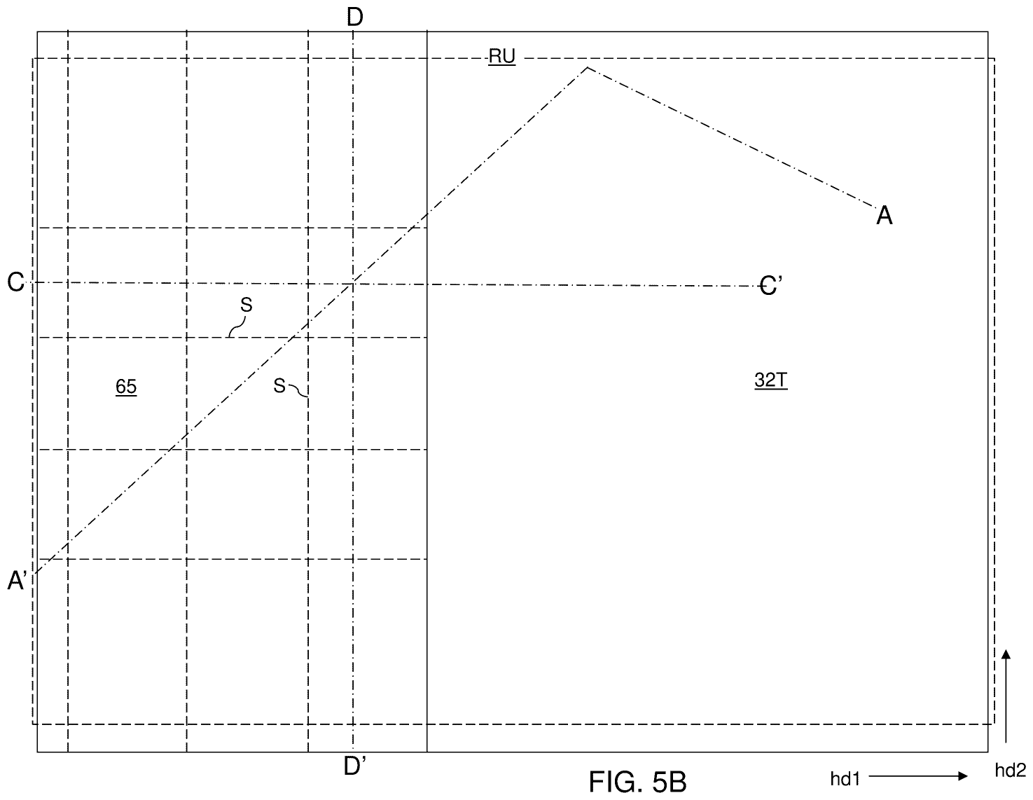

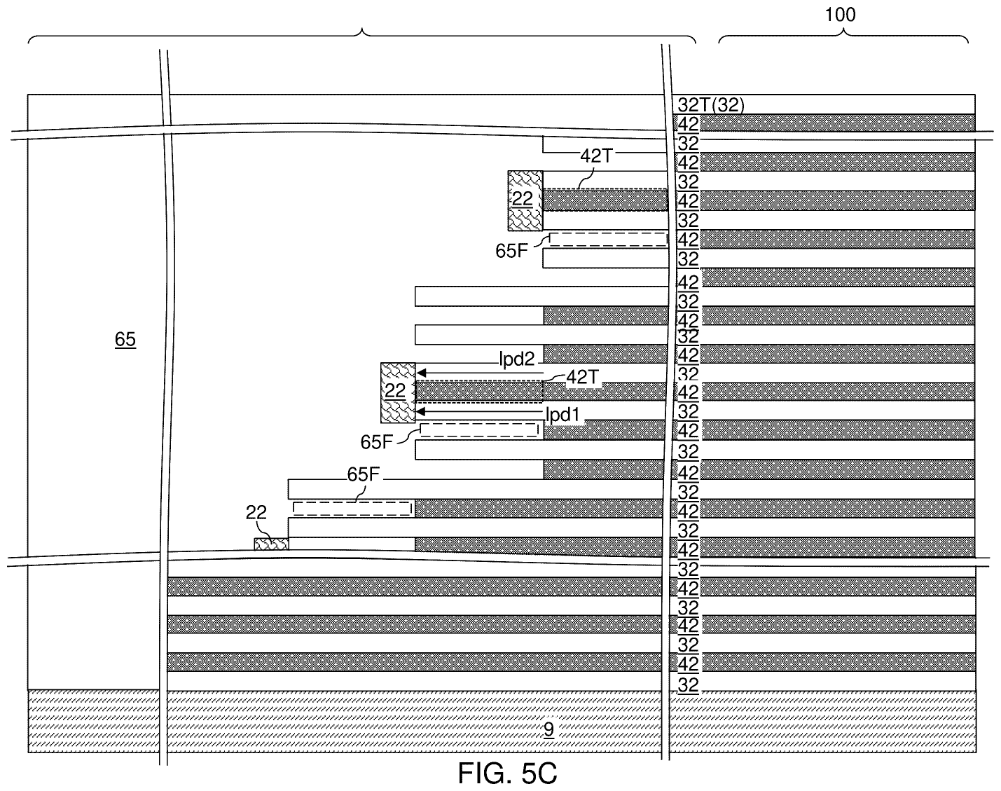

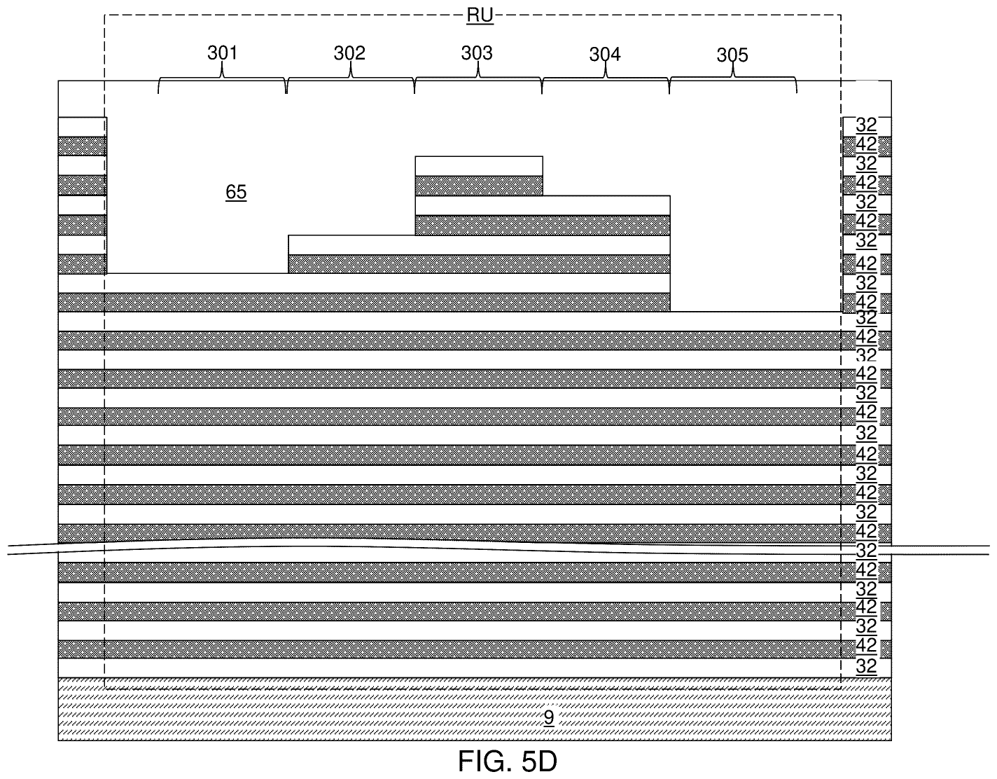

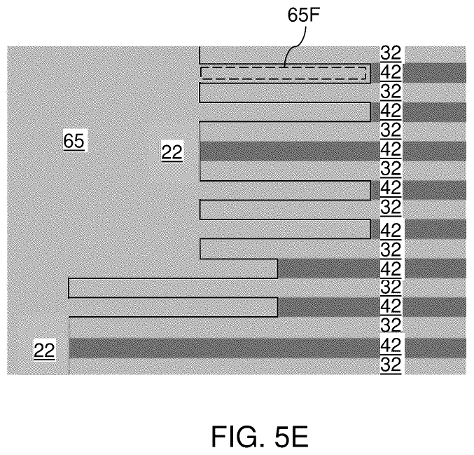

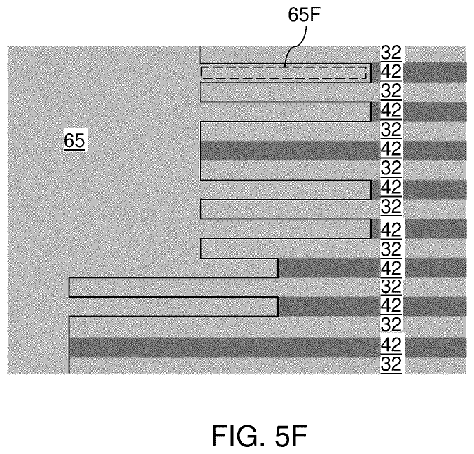

Referring to FIGS. 5A-5E, a dielectric material, such as undoped silicate glass (e.g., silicon oxide) or a doped silicate glass can be conformally deposited over the patterned surfaces of the alternating stack (32, 42). Excess portions of the deposited dielectric material can be removed from above the top surface of the topmost insulating layer 32T, for example, by chemical mechanical planarization (CMP). The remaining portion of the deposited dielectric material filling the stepped cavity constitutes a finned dielectric material portion 65, i.e., a dielectric material portion including dielectric fins 65F. Each of the dielectric fins 65F can be formed within a respective fin cavity 69F. If silicon oxide is employed for the finned dielectric material portion 65, the silicon oxide of the finned dielectric material portion 65 may optionally be doped with dopants such as B, P, and/or F. The top surface of the finned dielectric material portion 65 may be coplanar with the top surface of the topmost insulating layer 32T.

In one embodiment, each sacrificial material layer 42 within the subset of the sacrificial material layers 42 is located between a respective vertically-neighboring pair of the insulating layers 32, and the respective vertically-neighboring pair of the insulating layers 32 have sidewalls that laterally extend along the second horizontal direction hd2 and are vertically coincident with each other. As used herein, a first surface and a second surface are “vertically coincident” if the second surface overlies or underlies the first surface and if a vertical plane exists which contains the first surface and the second surface. In one embodiment, each sacrificial material layer 42 within the subset of the sacrificial material layers 42 is in direct contact with the respective vertically-neighboring pair of insulating layers 32, and has a respective sidewall that is vertically coincident with the sidewalls of the respective vertically-neighboring pair of insulating layers 32. In one embodiment, a respective first additional insulating layer 32 that underlies the respective vertically-neighboring pair of insulating layers 32 and a respective second additional insulating layer 32 that overlies the respective vertically-neighboring pair of insulating layers 32 have sidewalls that laterally extend along the second horizontal direction hd2 and are vertically coincident with the sidewalls of the respective vertically-neighboring pair of insulating layers 32.

In one embodiment shown in FIG. 5C, the respective tab portion 42T laterally protrudes away from the memory array region 100 relative to the respective underlying vertically-neighboring sacrificial material layer 42 by a first lateral protrusion distance lpd1. The respective tab portion 42T laterally protrudes away from the memory array region 100 relative to the respective overlying vertically-neighboring sacrificial material layer 42 by a second lateral protrusion distance lpd2, and the second lateral protrusion distance lpd2 may be the same as the first lateral protrusion distance lpd1. In one embodiment, the respective tab portion 42T laterally protrudes away from the memory array region 100 relative to a respective first additional sacrificial material layer 42 that underlies the respective underlying vertically-neighboring sacrificial material layer 42, and relative to a respective second additional sacrificial material layer 42 that overlies the respective overlying vertically-neighboring sacrificial material layer 42. In one embodiment, a sidewall of the respective first additional sacrificial material layer 42, a sidewall of the respective underlying vertically-neighboring sacrificial material layer 42, a sidewall of the respective second additional sacrificial material layer 42, and a sidewall of the respective overlying vertically-neighboring sacrificial material layer 42 are vertically coincident with each other.

The finned dielectric material portion 65 that includes laterally-extending dielectric fins 65F that extend into gaps between neighboring pair of insulating layers 32 among the insulating layers 32. In one embodiment, a tab portion 42T of the tab portions of the subset of the sacrificial material layers 42 is vertically spaced from a most proximal overlying one of the laterally-extending dielectric fins 65F by one of the insulating layers 32, and is vertically spaced from a most proximal underlying one of the laterally-extending dielectric fins 65F by another of the insulating layers 32. In one embodiment, a tab portion 42F of the tab portions of the subset of the sacrificial material layers 42 has an areal overlap with two overlying laterally-extending dielectric fins 65F and has an areal overlap with two underlying laterally-extending dielectric fins 65F. In one embodiment, a tab portion 42T of the tab portions of the subset of the sacrificial material layers 42 is laterally spaced from the finned dielectric material portion 65 by an etch-stop material portion 22; the etch-stop material portion 22 has a vertical extent that is less than a sum of twice a thickness of an insulating layer 32 among the insulating layers 32 and three times a thickness of an sacrificial material layer 42 among the sacrificial material layers 42; and the etch-stop material portion 22 has a top surface, a bottom surface, and a sidewall that contacts the finned dielectric material portion 65.

FIG. 5F is a vertical cross-sectional view of a region of an alternative embodiment of the exemplary structure at a processing step that corresponds to the processing steps of FIGS. 5A-5E. The alternative embodiment of the exemplary structure in FIG. 5F can be derived from the alternative configuration of the exemplary structure illustrated in FIGS. 3F and 4 by forming a finned dielectric material portion 65 as described with reference to FIGS. 5A-5E while the etch-stop material portions 22 are omitted.

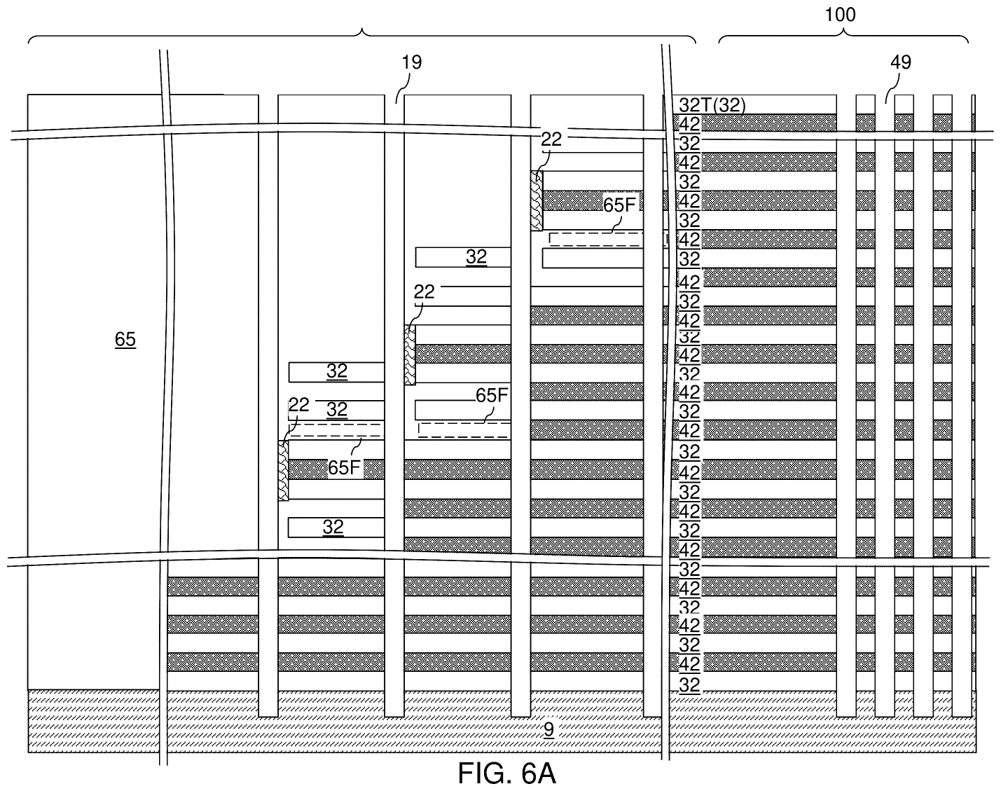

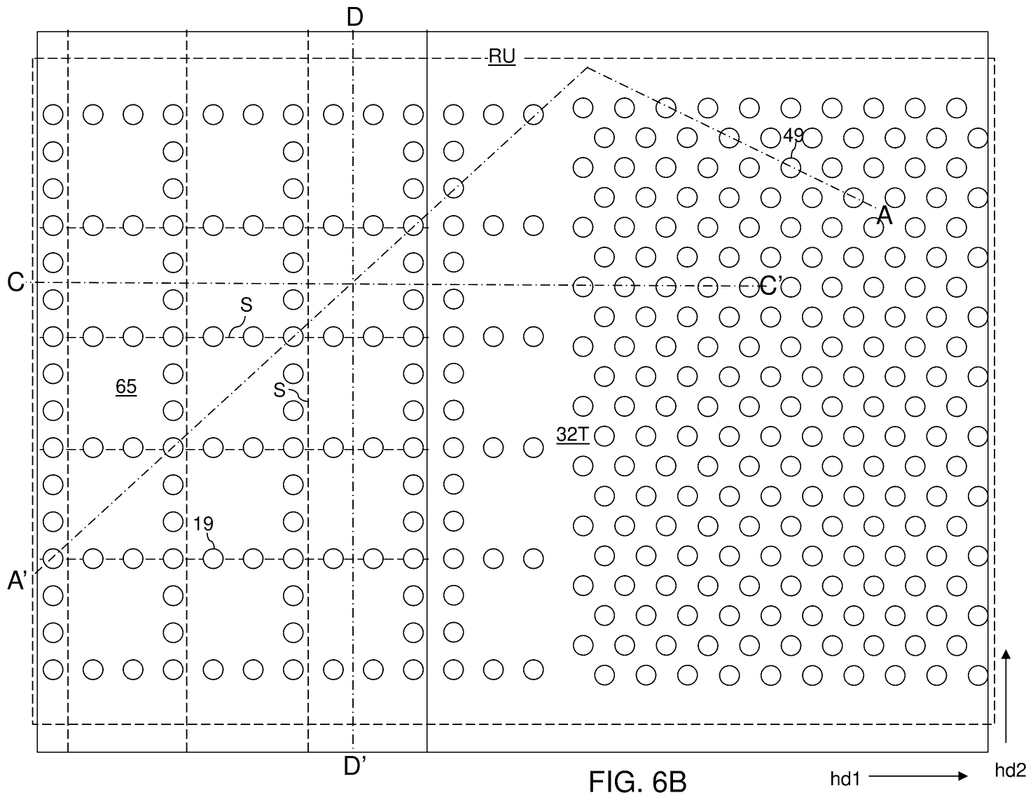

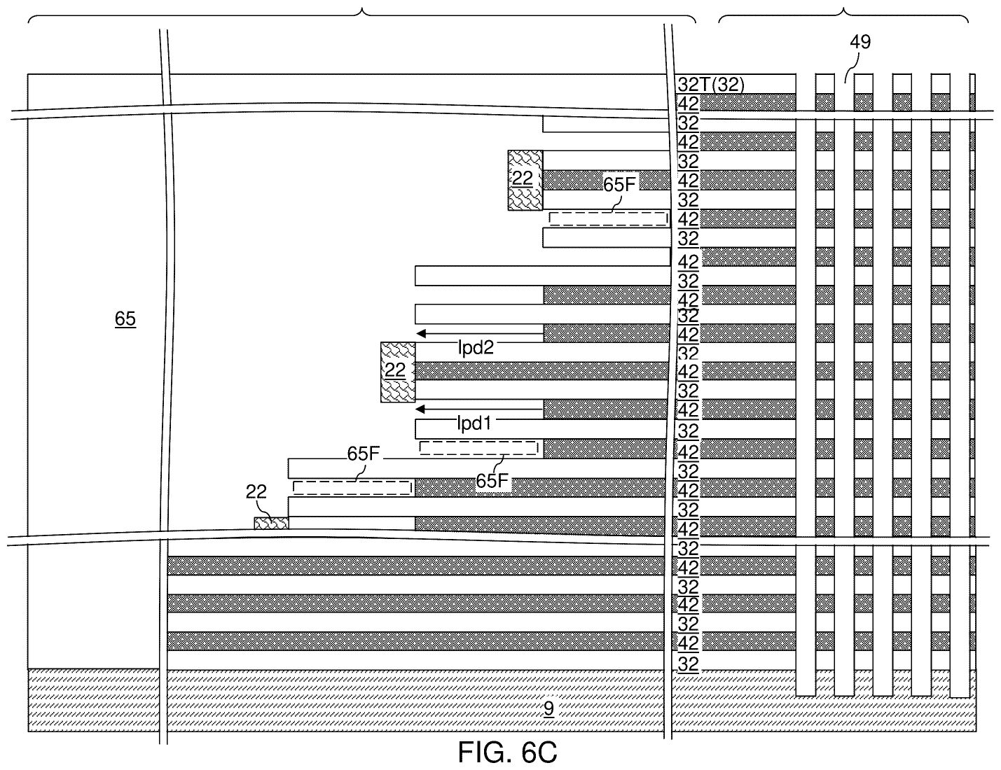

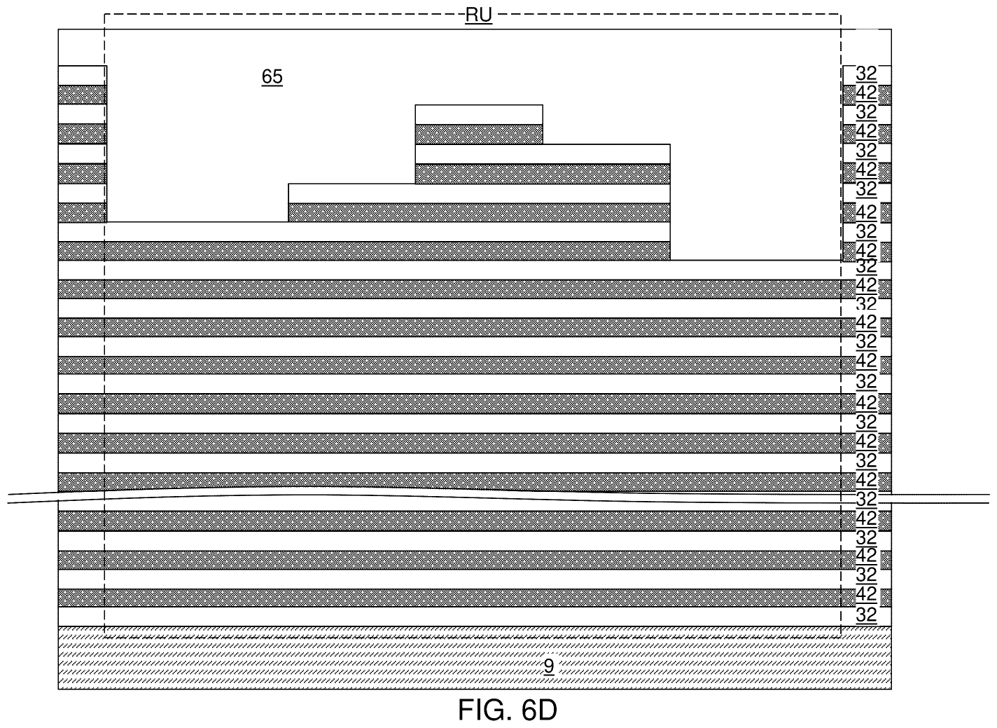

Referring to FIGS. 6A-6D, an etch mask layer (such as a photoresist layer) can be formed over the alternating stack (32, 42), and can be lithographically patterned to form openings in the memory array region 100 and in the contact region 300. An anisotropic etch process can be performed to transfer the pattern of the openings in the etch mask layer through the finned dielectric material portion 65 and the alternating stack (32, 42). Memory openings 49 are formed through the alternating stack (32, 42) in the memory array region 100. Support openings 19 can optionally be formed through the finned dielectric material portion 65 and the alternating stack (32, 42) in the contact region 300.

Each of the memory openings 49 and the support openings 19 can vertically extend into the carrier substrate 9. In one embodiment, bottom surfaces of the memory openings 49 and the support openings 19 may be formed at or below the top surface of the carrier substrate 9. The memory openings 49 may have a diameter in a range from 60 nm to 400 nm, such as from 120 nm to 300 nm, although lesser and greater thicknesses may be employed. The support openings 19 may have a diameter in a range from 60 nm to 400 nm, such as from 120 nm to 300 nm, although lesser and greater thicknesses may be employed.

Each cluster of memory openings 49 (which corresponds to an area of a memory block) may comprise a plurality of rows of memory openings 49. Each row of memory openings 49 may comprise a plurality of memory openings 49 that are arranged along the first horizontal direction (e.g., word line direction) hd1 with a uniform pitch. The rows of memory openings 49 may be laterally spaced from each other along the second horizontal direction (e.g., bit line direction) hd2, which may be perpendicular to the first horizontal direction hd1. In one embodiment, each cluster of memory openings 49 may be formed as a two-dimensional periodic array of memory openings 49.

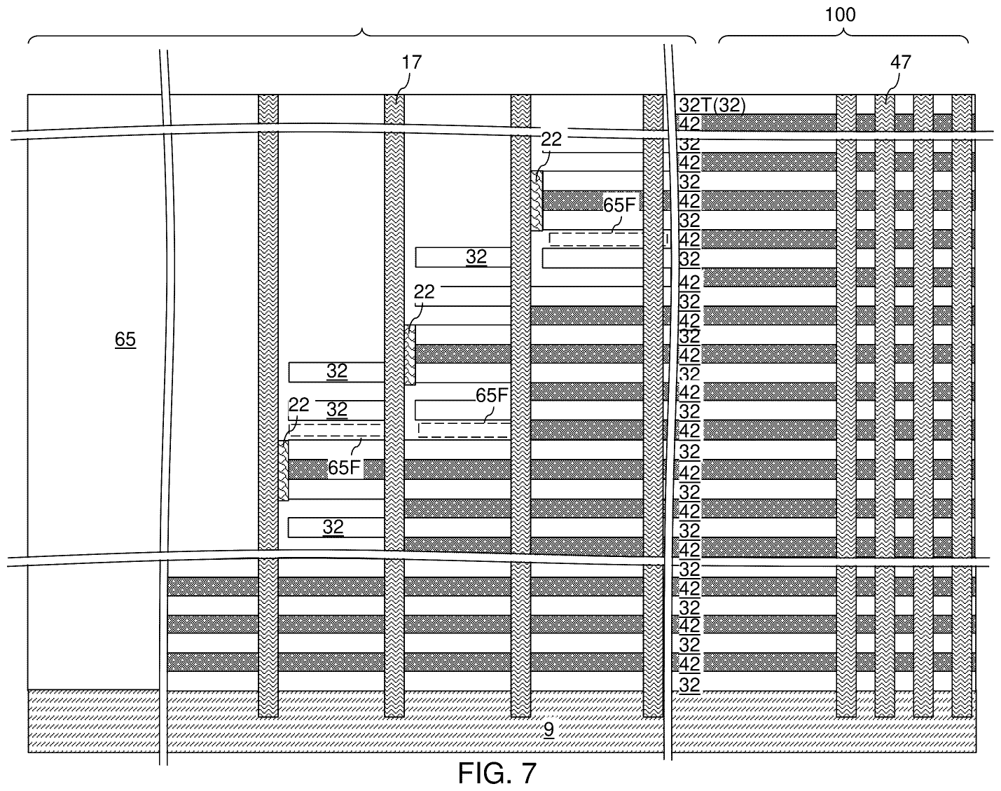

Referring to FIG. 7, an optional sacrificial liner layer (such as a thin silicon oxide layer) and a sacrificial fill material can be deposited in the memory openings 49 and in the support openings 19. The sacrificial fill material may comprise a carbon-based material (such as amorphous carbon or diamond-like carbon), a semiconductor material such as amorphous silicon or silicon-germanium), a polymer material, or a dielectric material (such as organosilicate glass or borosilicate glass). Excess portions of the sacrificial fill material may be removed from above the horizontal plane including the top surface of the topmost insulating layer 32T. Each remaining portion of the sacrificial fill material that fills a memory opening 49 constitutes a sacrificial memory opening fill structure 48. Each remaining portion of the sacrificial fill material that fill a support opening 19 constitutes a sacrificial support opening fill structure 18.

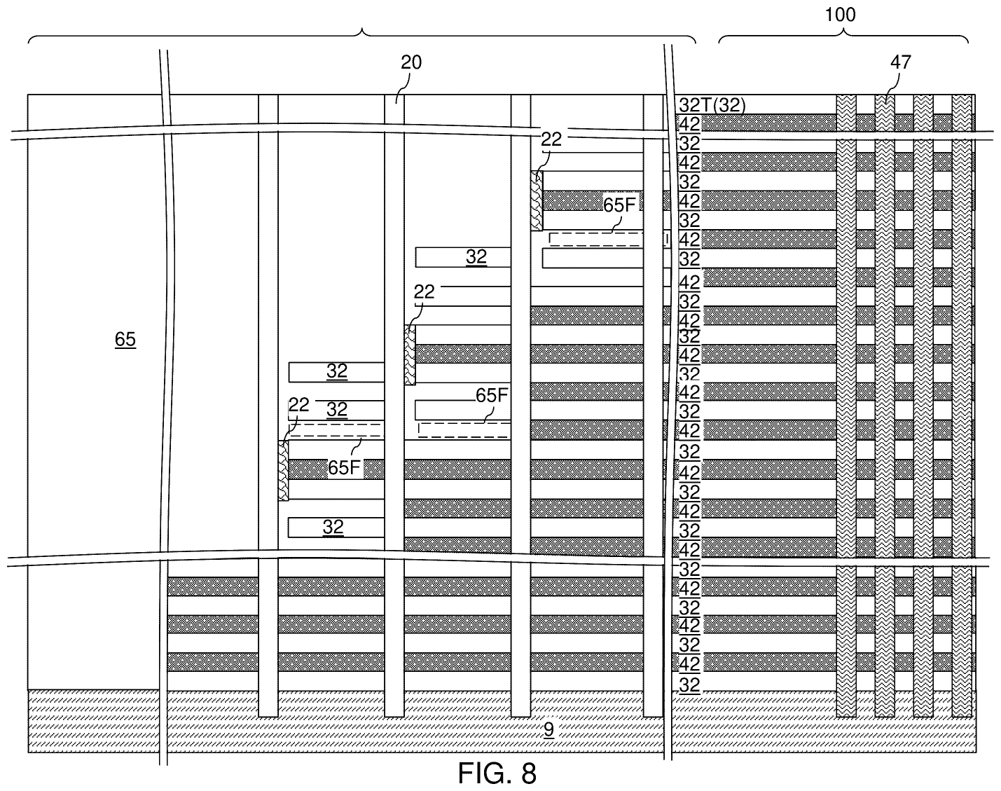

Referring to FIG. 8, a photoresist layer (not shown) can be applied over the exemplary structure, and can be lithographically patterned to cover the sacrificial memory opening fill structures 48 in the memory array region 100 without covering the sacrificial support opening fill structures 18 in the contact region 300. The sacrificial support opening fill structures 18 are subsequently removed selective to the materials of the insulating layers 32, the sacrificial material layers 42, and the carrier substrate 9 by ashing or selective etching. Voids are formed in the volumes of the support openings 19 from which the sacrificial support opening fill structures 18 are removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the finned dielectric material portion 65 during replacement of the sacrificial material layers 42 with electrically conductive layers. Alternatively, the support openings 19 can be formed at a later step at the same time as the memory openings, and the support pillar structures 20 can be formed in the support openings 19 at the same time as the memory opening fill structures are formed in the memory openings, as will be described below.

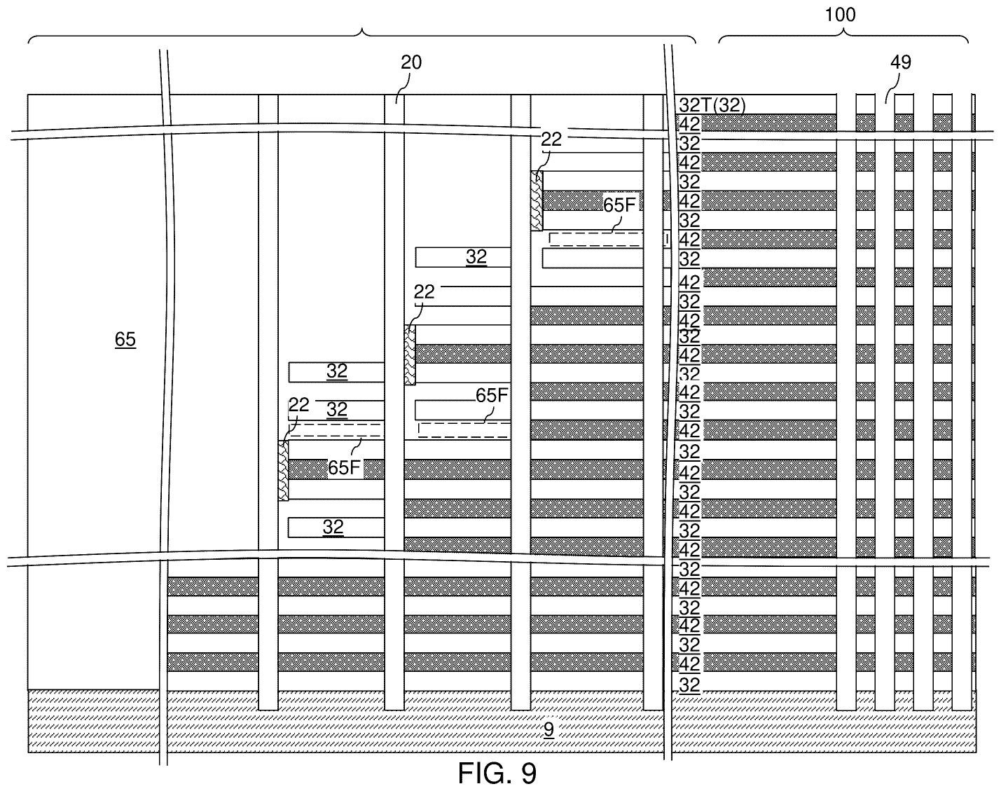

Referring to FIG. 9, sacrificial memory opening fill structures 48 are subsequently removed selective to the materials of the insulating layers 32, the sacrificial material layers 42, and the carrier substrate 9. Voids are formed in the volumes of the memory openings 49 from which the sacrificial memory opening fill structures 48 are removed.

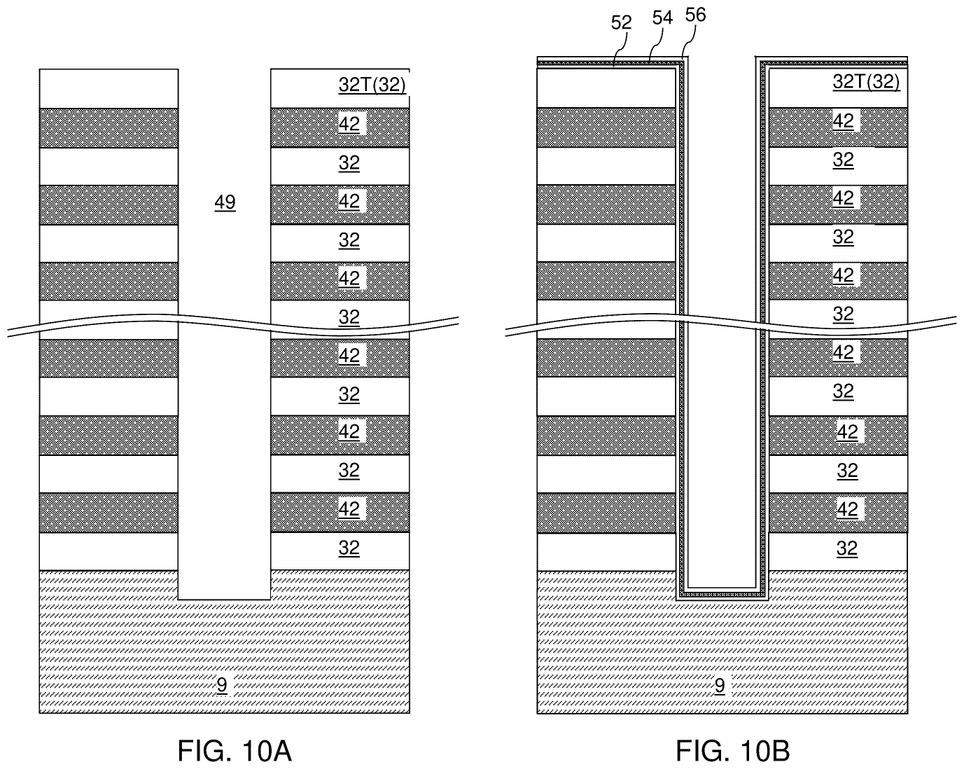

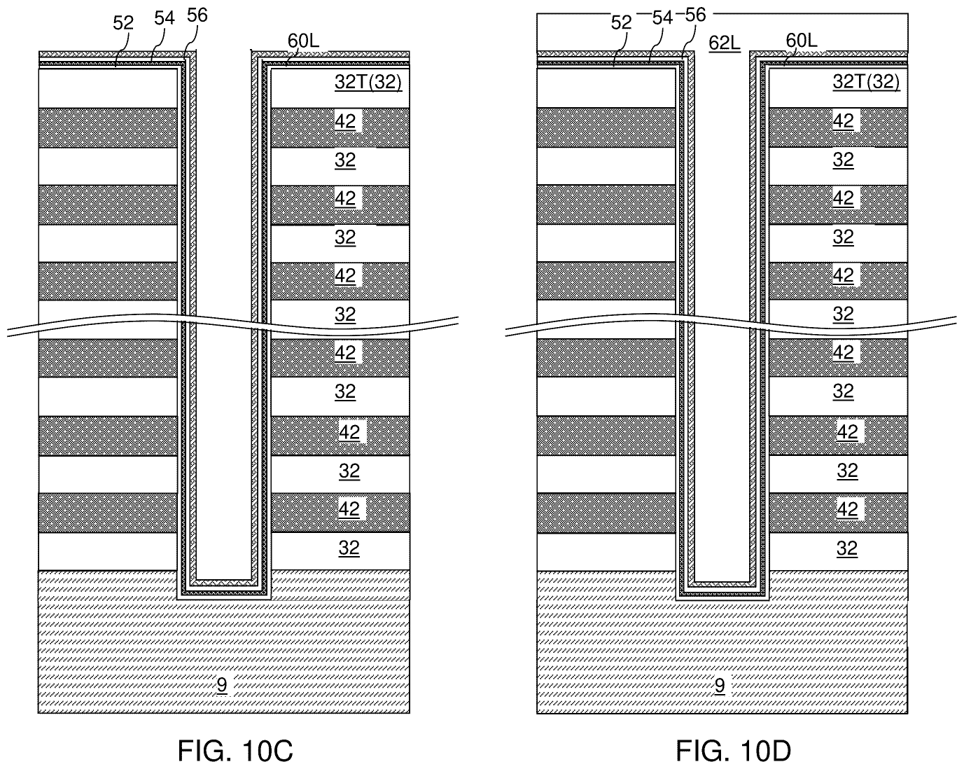

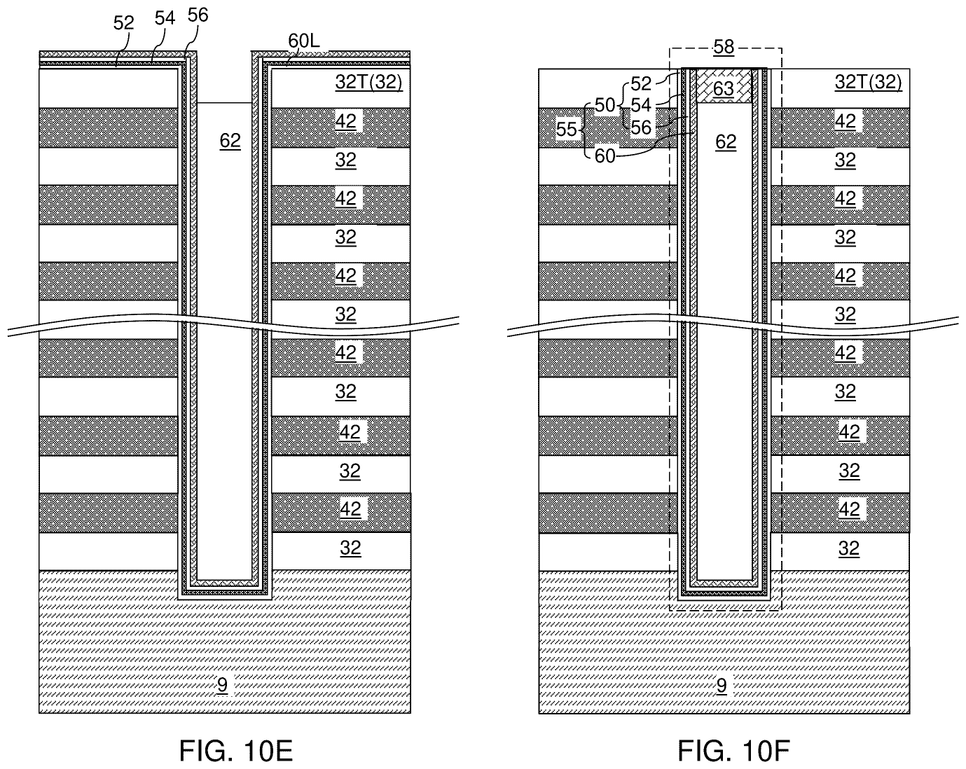

FIGS. 10A-10F are sequential vertical cross-sectional views of a memory opening 49 during formation of a memory opening fill structure 58 according to an embodiments of the present disclosure.

Referring to FIG. 10A, a memory opening 49 is illustrated after the processing steps of FIG. 9.

Referring to FIG. 10B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprises a charge storage material, the optional dielectric liner 56 may comprise a tunneling dielectric layer.

Referring to FIG. 10C, a semiconductor channel material layer 60L can be deposited over each memory film 50 by performing a conformal deposition process. If the semiconductor channel material layer 60L is doped, the semiconductor channel material layer 60L may have a doping of a first conductivity type, which may be p-type or n-type. The thickness of the semiconductor channel material layer 60L may be in a range from 5 nm to 50 nm, such as from 10 nm to 30 nm, although lesser and greater thicknesses may also be employed.

Referring to FIG. 10D, a dielectric core layer 62L comprising a dielectric fill material, such as silicon oxide, can be deposited in remaining volumes of the memory openings 49. While the dielectric core layer 62L can be deposited employing a conformal deposition process, such as a chemical vapor deposition process, the conformity of the conformal deposition process may not be perfect. Thus, the thickness of a bottom portion of the dielectric core layer 62L at the bottom of each memory opening 49 may be less than the thickness of an upper portion of the dielectric core layer 62L at the top of each memory opening 49.

Referring to FIG. 10E, the dielectric core layer 62L can be vertically recessed such that each remaining portion of the dielectric core layer has a top surface at, or about, the horizontal plane including the bottom surface of the topmost insulating layers 32. Each remaining portion of the dielectric core layer constitutes a dielectric core 62.

Referring to FIG. 10F, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5×10¹⁸/cm³ to 2×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel material layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

In the alternative embodiment, the support pillar structures 20 may be formed in the support openings 19 at the same time as the memory opening fill structures 58 are formed in the memory openings 49. In this case, the support pillar structures 20 comprise the same materials as the memory opening fill structures 58.

An anneal process can be performed to activate electrical dopants in the drain region 63 and in the vertical semiconductor channel 60. In this case, any amorphous semiconductor material in the vertical semiconductor channel 60 is converted into a polycrystalline semiconductor material.

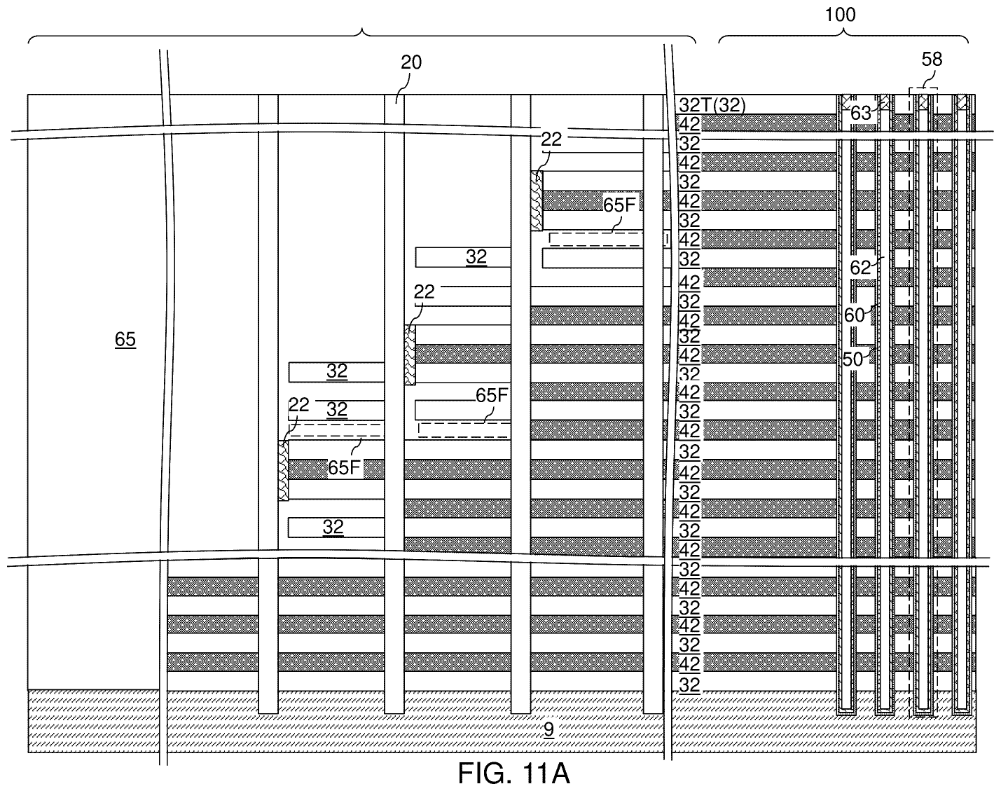

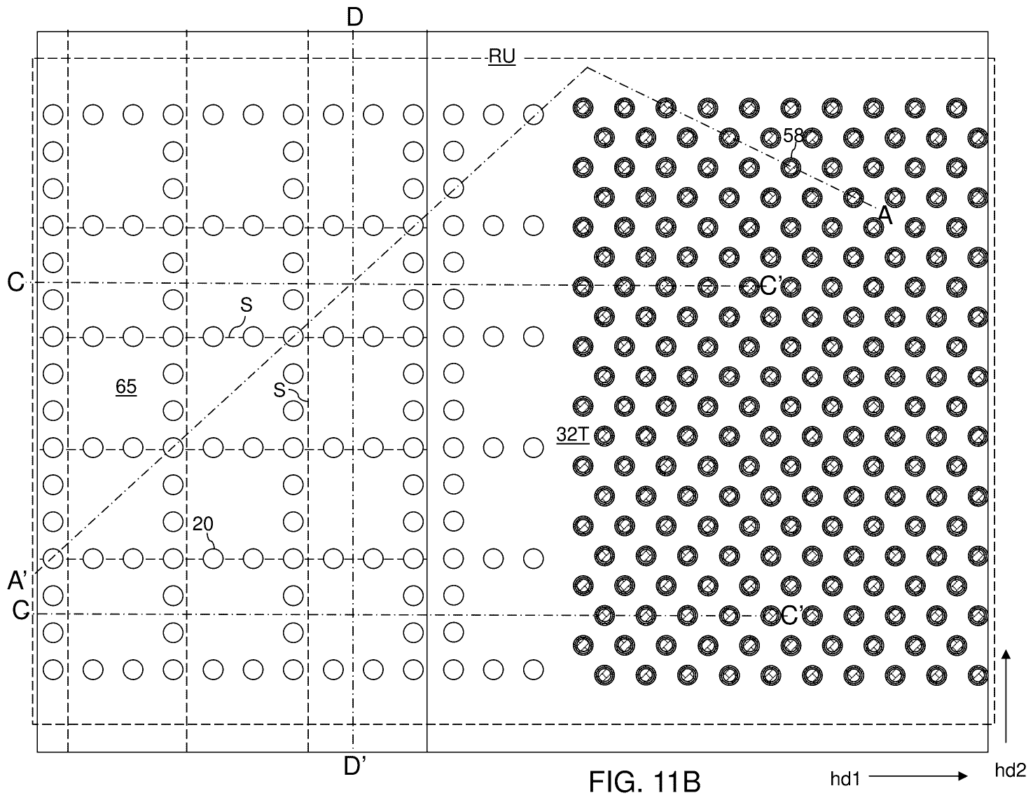

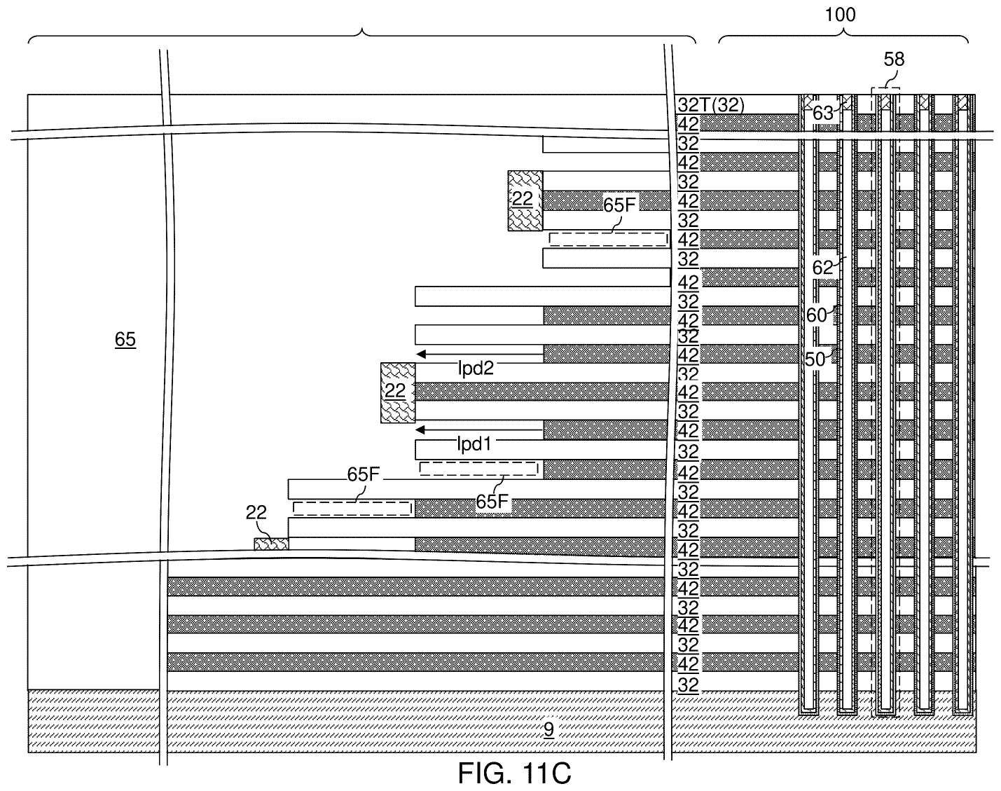

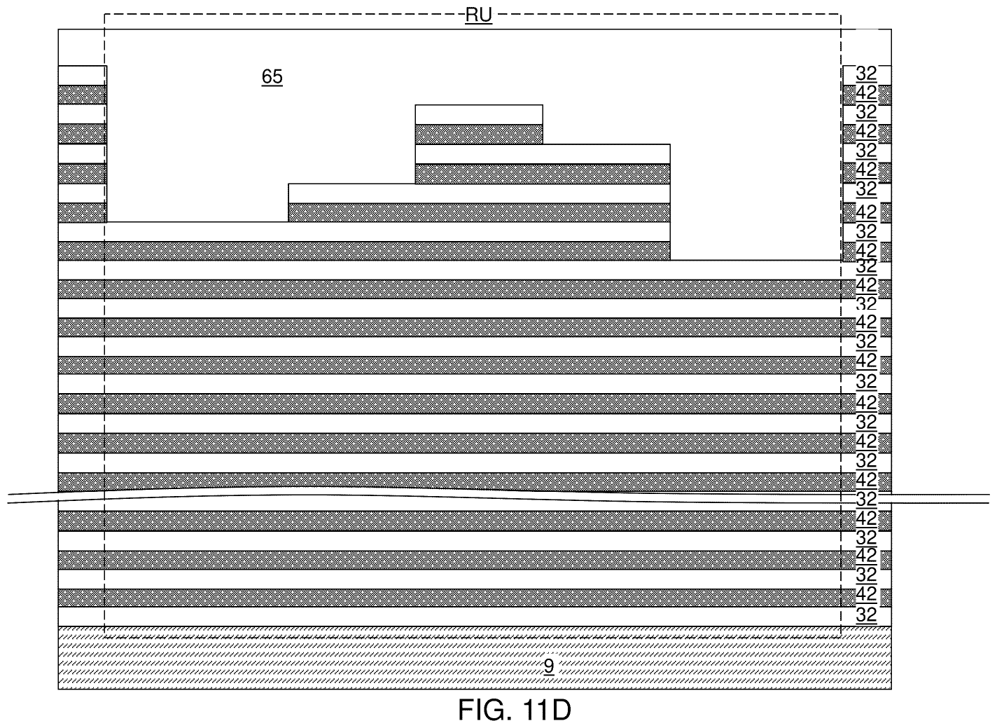

Referring to FIGS. 11A-11D, the exemplary structure is illustrated after formation of memory opening fill structures 58 within the memory openings 49. The memory opening fill structures 58 are located in the memory openings 49. Each of the memory opening fill structures 58 comprises a respective memory film 50 and a respective vertical semiconductor channel 60.

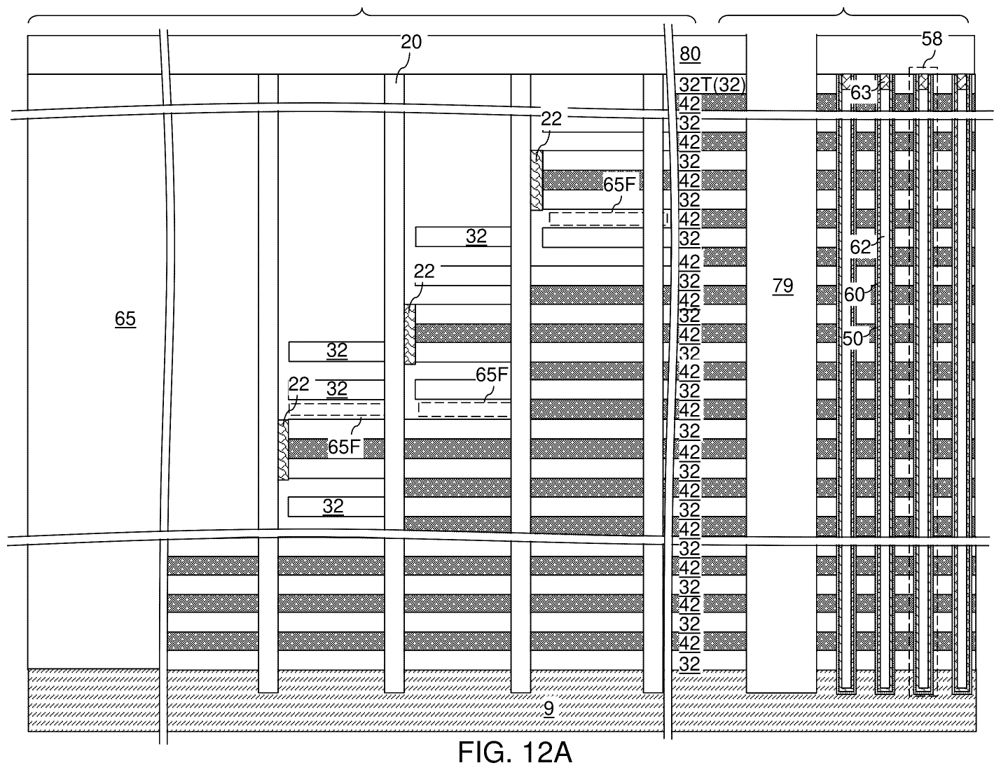

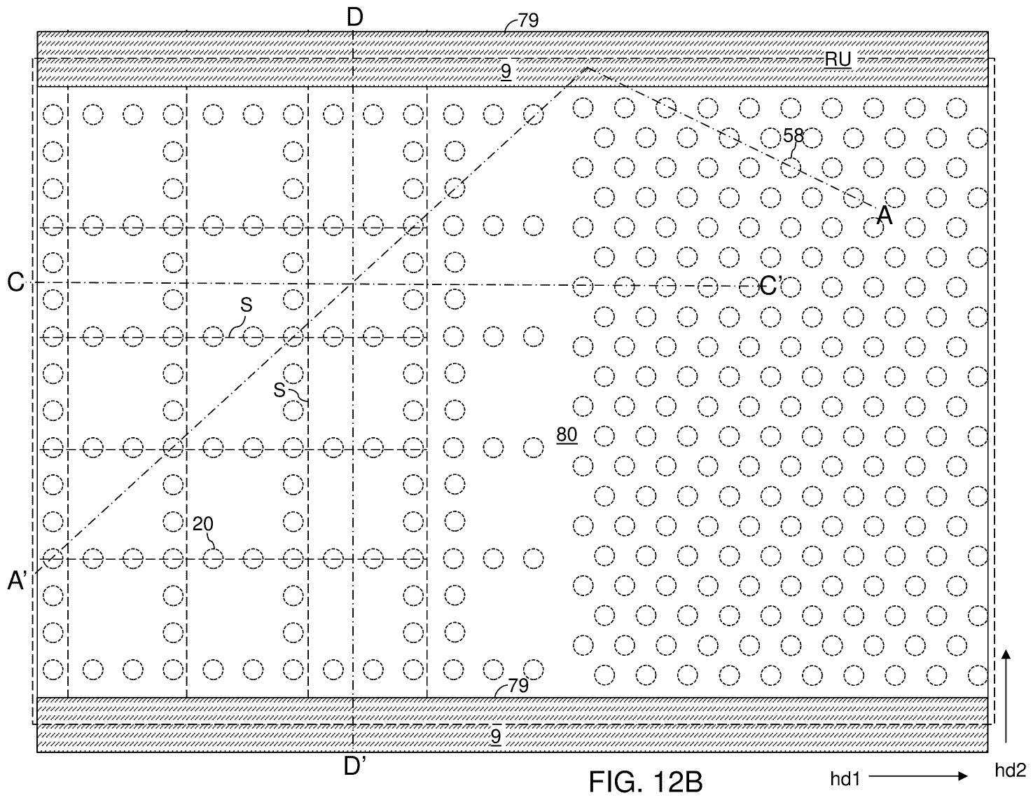

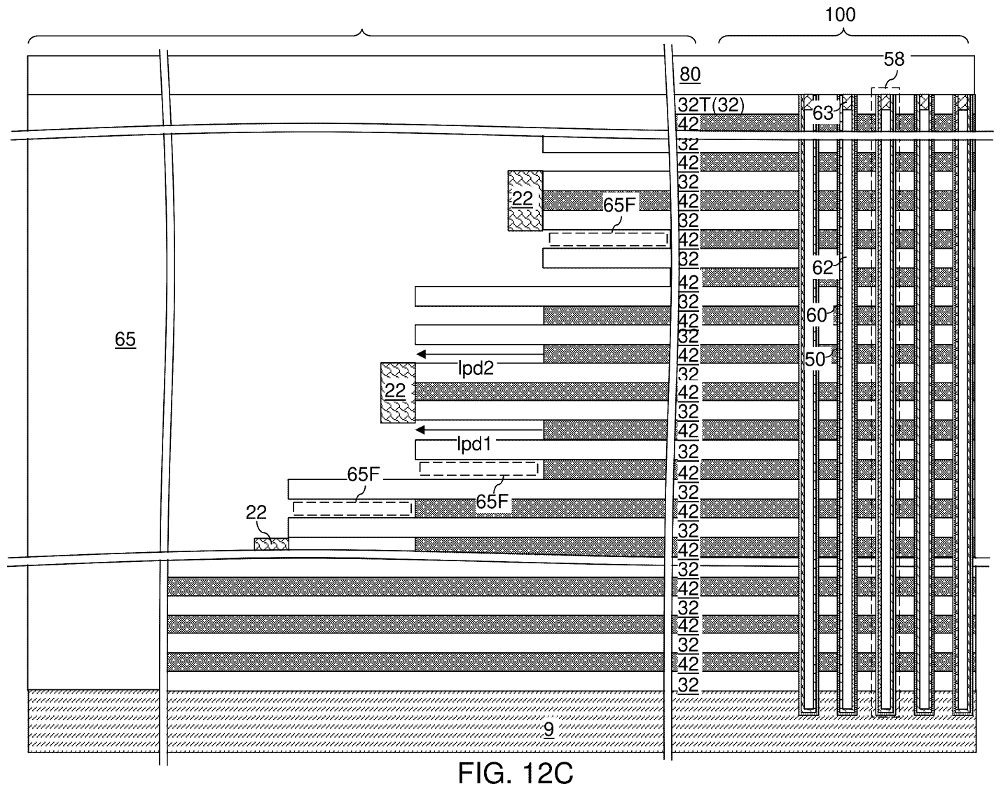

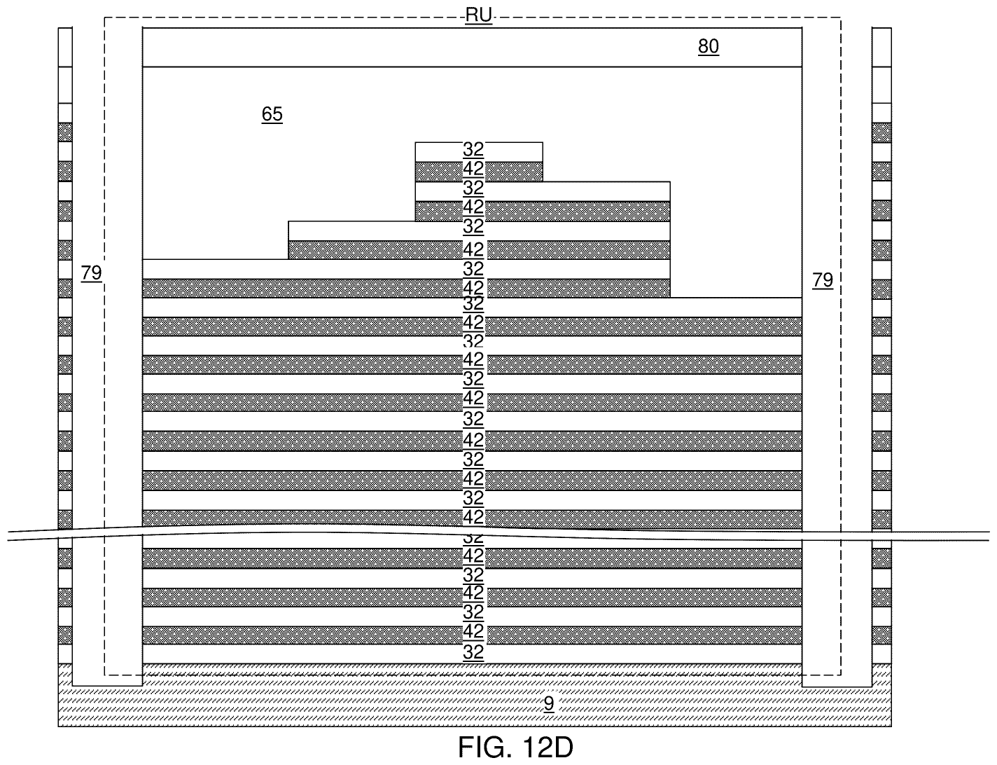

Referring to FIGS. 12A-12D, a dielectric material, such as undoped silicate glass (i.e., silicon oxide) or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), and the finned dielectric material portion 65, and to a top surface of the carrier substrate 9. Lateral isolation trenches 79 laterally extending along the first horizontal direction hd1 can be formed through the alternating stack (32, 42), the finned dielectric material portion 65, and the contact-level dielectric layer 80. Each of the lateral isolation trenches 79 may comprise a respective pair of lengthwise sidewalls that are parallel to the first horizontal direction hd1 and vertically extend from the top surface of the contact-level dielectric layer 80 to the top surface of the carrier substrate 9. A surface of the carrier substrate 9 can be physically exposed underneath each lateral isolation trench 79. The photoresist layer can be subsequently removed, for example, by ashing.

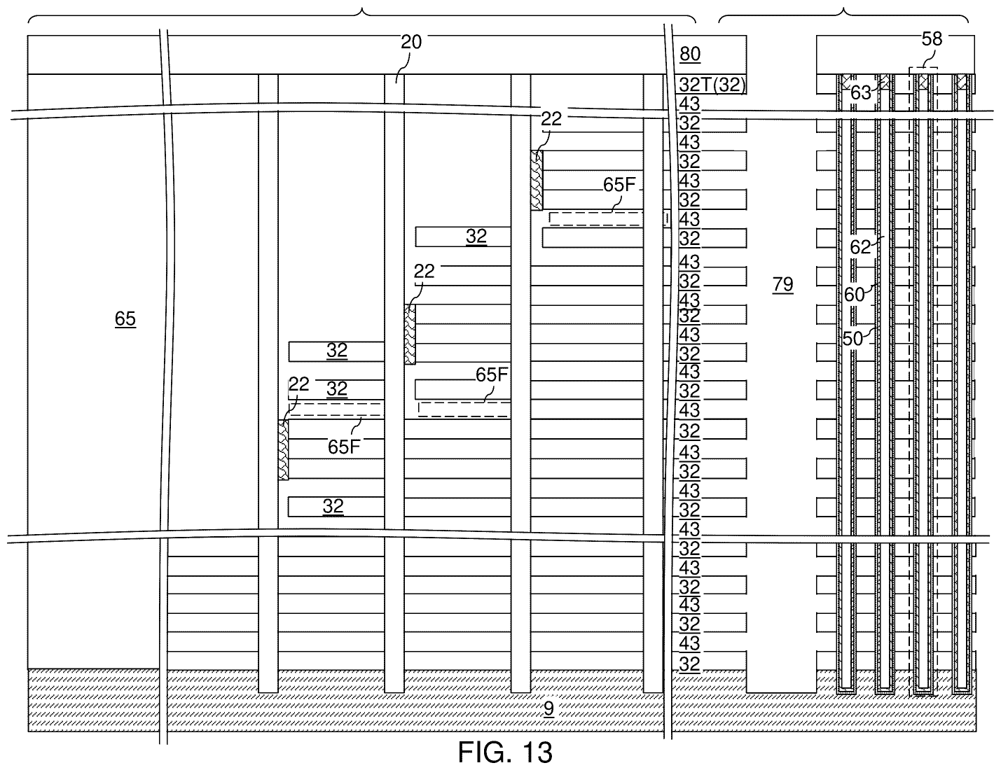

Referring to FIG. 13, an etchant that selectively etches the material of the sacrificial material layers 42 with respect to the material of the insulating layers 32 and the etch-stop material portions 22 (if present) can be introduced into the lateral isolation trenches 79, for example, employing an isotropic etch process. Laterally-extending cavities 43 are formed in volumes from which the sacrificial material layers 42 are removed. The removal of the sacrificial material layers 42 can be selective to the materials of the insulating layers 32, the finned dielectric material portion 65, the material of the outermost layer of the memory films 50, and the material of the etch-stop material portions 22 (if present). In one embodiment, the sacrificial material layers 42 can include silicon nitride, and the materials of the insulating layers 32 and the finned dielectric material portion 65 can include silicon oxide.

The etch process that removes the second material selective to the first material and the outermost layer of the memory films 50 can be a wet etch process employing a wet etch solution, or can be a gas phase (dry) etch process in which the etchant is introduced in a vapor phase into the lateral isolation trenches 79. For example, if the sacrificial material layers 42 include silicon nitride, the etch process can be a wet etch process in which the exemplary structure is immersed within a wet etch tank including phosphoric acid, which etches silicon nitride selective to silicon oxide, silicon, and various other materials employed in the art. The support pillar structure 20, the finned dielectric material portion 65, and the memory stack structures 55 provide structural support while the laterally-extending cavities 43 are present within volumes previously occupied by the sacrificial material layers 42.

Each laterally-extending cavity 43 can be a laterally extending cavity having a lateral dimension that is greater than the vertical extent of the cavity. In other words, the lateral dimension of each laterally-extending cavity 43 can be greater than the height of the laterally-extending cavity 43. A plurality of laterally-extending cavities 43 can be formed in the volumes from which the second material of the sacrificial material layers 42 is removed. The memory openings in which the memory stack structures 55 are formed are herein referred to as front side openings or front side cavities in contrast with the laterally-extending cavities 43.

Each of the plurality of laterally-extending cavities 43 can extend substantially parallel to the top surface of the carrier substrate 9. A laterally-extending cavity 43 can be vertically bounded by a top surface of an underlying insulating layer 32 and a bottom surface of an overlying insulating layer 32. In one embodiment, each laterally-extending cavity 43 can have a uniform height throughout.

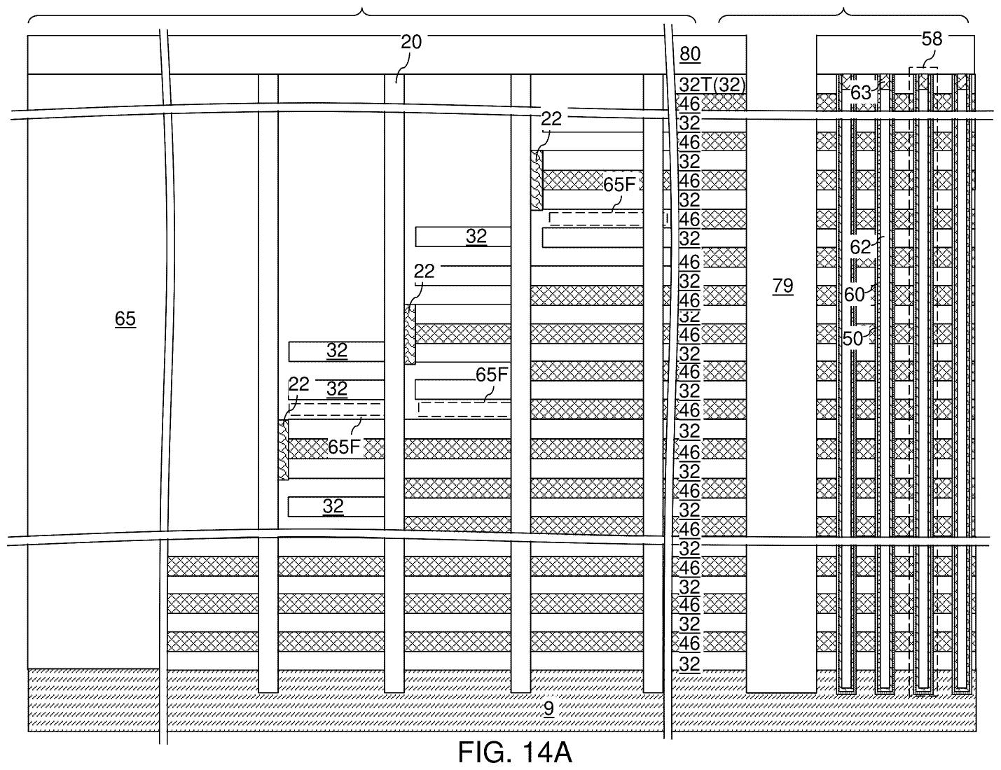

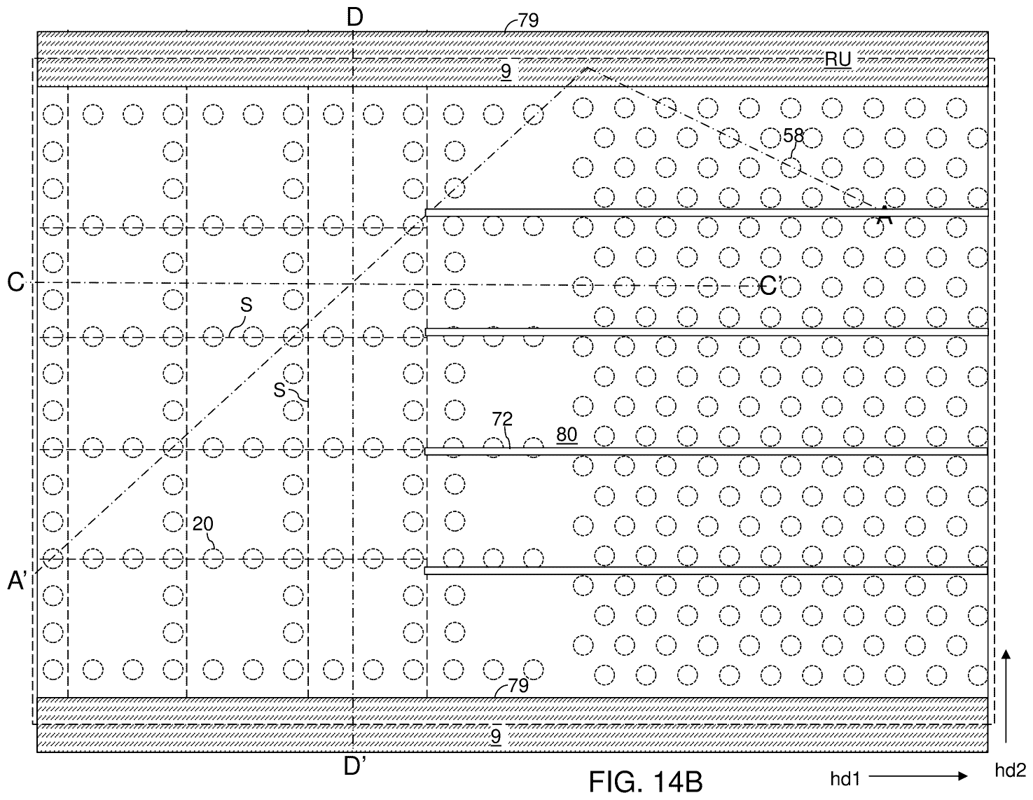

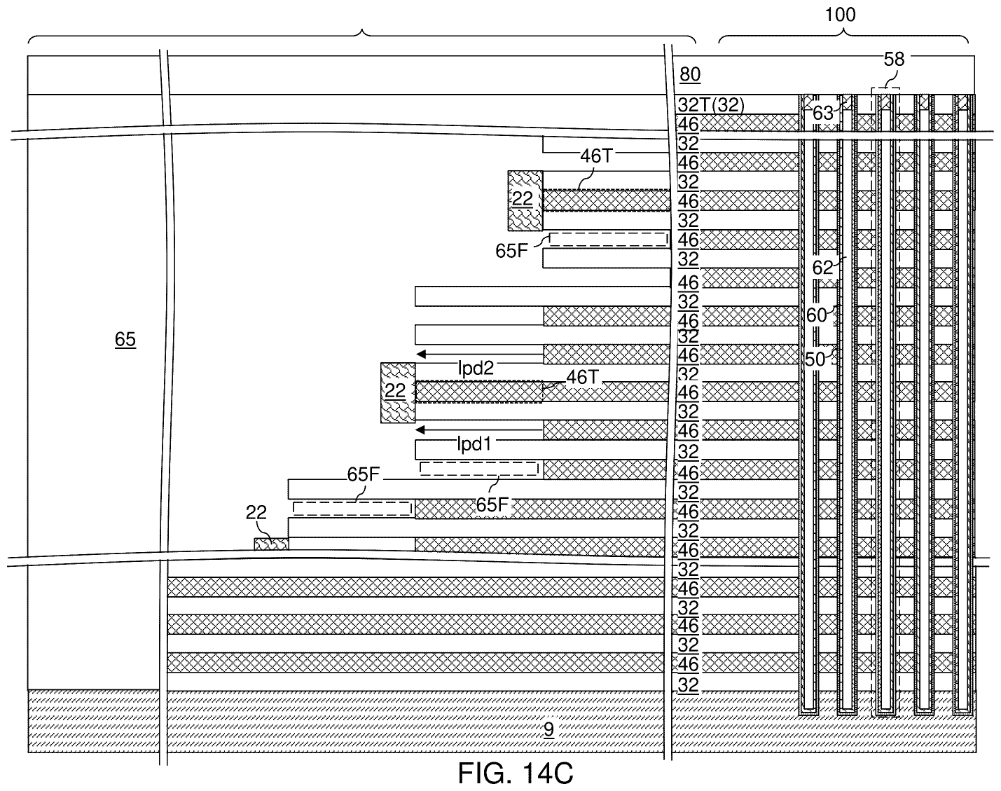

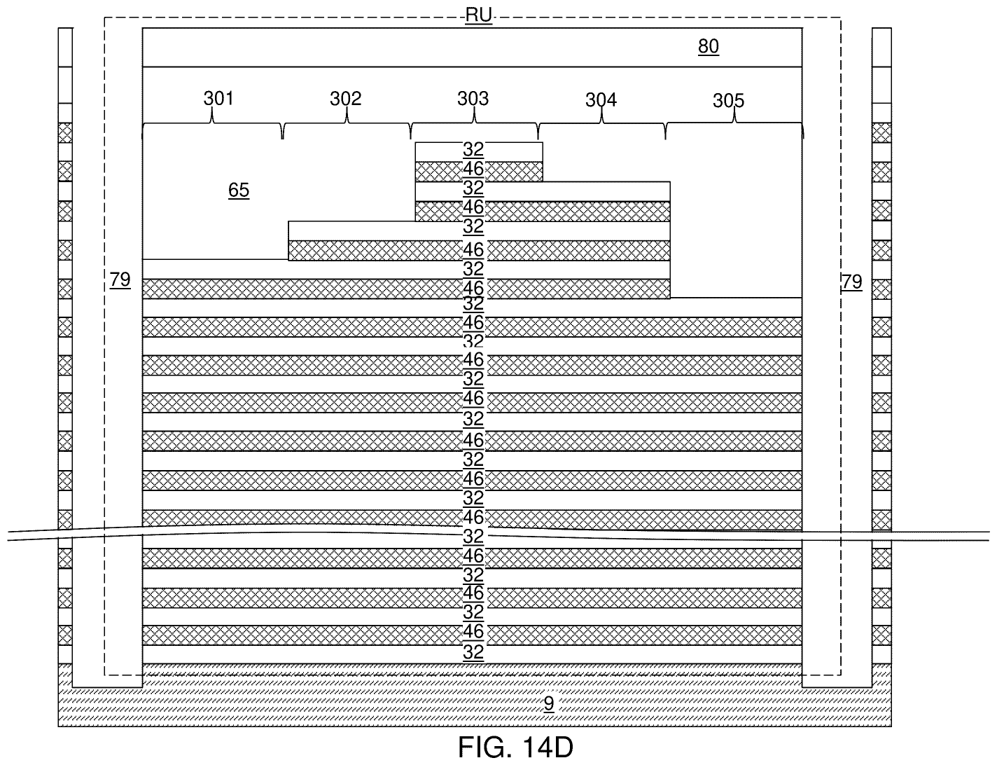

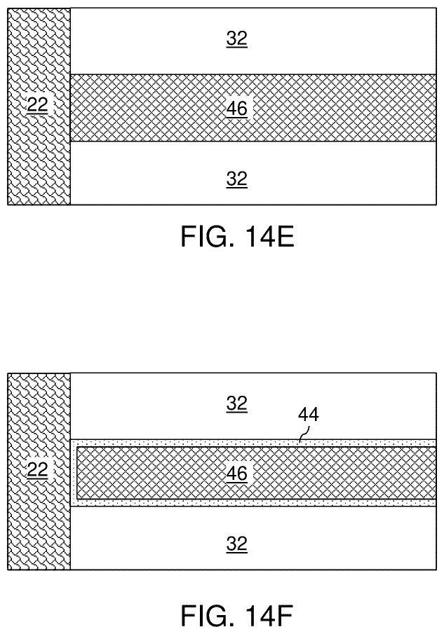

Referring to FIGS. 14A-14F, an outer blocking dielectric layer 44 can be optionally formed. FIG. 14E illustrates a configuration in which the outer blocking dielectric layer 44 is not employed. FIG. 14F illustrates a configuration in which the outer blocking dielectric layer 44 is employed. The outer blocking dielectric layer 44, if present, comprises a dielectric material that functions as a control gate dielectric for the control gates to be subsequently formed in the laterally-extending cavities 43. In case the blocking dielectric layer 52 is present within each memory opening, the outer blocking dielectric layer 44 is optional. In case the blocking dielectric layer 52 is omitted, the outer blocking dielectric layer 44 is present.

At least one conductive material can be deposited in the laterally-extending cavities 43 by providing at least one reactant gas into the laterally-extending cavities 43 through the lateral isolation trenches 79. A metallic barrier layer can be deposited in the laterally-extending cavities 43. The metallic barrier layer includes an electrically conductive metallic material that can function as a diffusion barrier layer and/or adhesion promotion layer for a metallic fill material to be subsequently deposited. The metallic barrier layer can include a conductive metallic nitride material such as TiN, TaN, WN, or a stack thereof, or can include a conductive metallic carbide material such as TiC, TaC, WC, or a stack thereof. In one embodiment, the metallic barrier layer can be deposited by a conformal deposition process such as chemical vapor deposition (CVD) or atomic layer deposition (ALD). The thickness of the metallic barrier layer can be in a range from 2 nm to 8 nm, such as from 3 nm to 6 nm, although lesser and greater thicknesses can also be employed. In one embodiment, the metallic barrier layer can consist essentially of a conductive metal nitride such as TiN.

A metal fill material is deposited in the plurality of laterally-extending cavities 43, on the sidewalls of the at least one the lateral isolation trench 79, and over the top surface of the contact-level dielectric layer 80 to form a metallic fill material layer. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer can consist essentially of at least one elemental metal. The at least one elemental metal of the metallic fill material layer can be selected, for example, from tungsten, cobalt, ruthenium, titanium, and tantalum. In one embodiment, the metallic fill material layer can consist essentially of a single elemental metal. In one embodiment, the metallic fill material layer can be deposited employing a fluorine-containing precursor gas such as WF₆. In one embodiment, the metallic fill material layer can be a tungsten layer including a residual level of fluorine atoms as impurities. The metallic fill material layer is spaced from the insulating layers 32 and the memory stack structures 55 by the metallic barrier layer, which is a metallic barrier layer that blocks diffusion of fluorine atoms therethrough.

A plurality of electrically conductive layers 46 can be formed in the plurality of laterally-extending cavities 43, and a continuous metallic material layer can be formed on the sidewalls of each lateral isolation trench 79 and over the contact-level dielectric layer 80. Each electrically conductive layer 46 includes a portion of the metallic barrier layer and a portion of the metallic fill material layer that are located between a vertically neighboring pair of dielectric material layers such as a pair of insulating layers 32. The continuous metallic material layer includes a continuous portion of the metallic barrier layer and a continuous portion of the metallic fill material layer that are located in the lateral isolation trenches 79 or above the contact-level dielectric layer 80.

The deposited metallic material of the continuous electrically conductive material layer is etched back from the sidewalls of each lateral isolation trench 79 and from above the contact-level dielectric layer 80 by performing an isotropic etch process that etches the at least one conductive material of the continuous electrically conductive material layer. Each remaining portion of the deposited metallic material in the laterally-extending cavities 43 constitutes an electrically conductive layer 46. Each electrically conductive layer 46 can be a conductive line structure. Thus, the sacrificial material layers 42 are replaced with the electrically conductive layers 46. Generally, the electrically conductive layers 46 can be formed by providing a metallic precursor gas into the lateral isolation trenches 79 and into the laterally-extending cavities 43.

At least one uppermost electrically conductive layer 46 may comprise a drain side select gate electrode. At least one bottommost electrically conductive layer 46 may comprise a source side select gate electrode. The remaining electrically conductive layers 46 may comprise word lines. Each word line functions as a common control gate electrode for the plurality of vertical NAND strings (e.g., memory opening fill structures 58).

Memory openings 49 vertically extending through the alternating stack (32, 46) in a memory array region 100. In one embodiment, a subset of the electrically conductive layers 46 (such as the word lines) comprise a respective tab portion 46T that overlies and has an areal overlap in a plan view with a respective underlying laterally-extending dielectric fin 65F. In one embodiment, the respective tab portion 46T underlies and has an areal overlap in the plan view with a respective overlying laterally-extending dielectric fin 65F. Each electrically conductive layer 46 within the subset of the electrically conductive layers 46 comprises a respective tab portion 46T that laterally protrudes away from the memory array region 100 relative to a respective underlying vertically-neighboring electrically conductive layer 46 and relative to a respective overlying vertically-neighboring electrically conductive layer 46,

In one embodiment, each layer within the alternating stack (32, 46) laterally extends along a first horizontal direction hd1 and has a uniform layer stack width along a second horizontal direction hd2 in the memory array region 100. The uniform layer stack width is the lateral spacing between a neighboring pair of lateral isolation trenches 79 (e.g., width of a memory block). In one embodiment, the tab portions 46T of the subset of the electrically conductive layers 46 laterally protrude along the first horizontal direction hd1. In one embodiment, the tab portions 46T have a respective tab width that is less than the uniform layer stack width. In one embodiment, the tab width may be 1/M times the uniform layer stack width, in which M is the total number of staircases (301, 302, 303, 304, 305) between a neighboring pair of lateral isolation trenches 79. In the example shown in FIG. 14D, M=5.

In one embodiment, each electrically conductive layer 46 within the subset of the electrically conductive layers 46 is located between a respective vertically-neighboring pair of the insulating layers 32. The respective vertically-neighboring pair of insulating layers 32 have sidewalls that laterally extend along the second horizontal direction hd2 and are vertically coincident with each other.

In one embodiment, each electrically conductive layer 46 within the subset of the electrically conductive layers 46 is in direct contact with the respective vertically-neighboring pair of insulating layers 32, and has a respective sidewall that is vertically coincident with the sidewalls of the respective vertically-neighboring pair of insulating layers 32, as illustrated in FIG. 14E.

In an alternative embodiment, each electrically conductive layer 46 within the subset of the electrically conductive layers 46 is spaced from the respective vertically-neighboring pair of insulating layers 32 by a respective outer blocking dielectric layer 44, and has a respective sidewall that is laterally offset from the sidewalls of the respective vertically-neighboring pair of insulating layers 32 by a thickness of the respective outer blocking dielectric layer 44, as illustrated in FIG. 14F.

In one embodiment, a respective first additional insulating layer 32 that underlies the respective vertically-neighboring pair of insulating layers 32 and a respective second additional insulating layer 32 that overlies the respective vertically-neighboring pair of insulating layers 32 have sidewalls that laterally extend along the second horizontal direction hd2 and are vertically coincident with the sidewalls of the respective vertically-neighboring pair of insulating layers 32.

In one embodiment illustrated in FIG. 14C, the respective tab portion 46T laterally protrudes away from the memory array region 100 relative to the respective underlying vertically-neighboring electrically conductive layer 46 by a first lateral protrusion distance lpd1; the respective tab portion 46T laterally protrudes away from the memory array region 100 relative to the respective overlying vertically-neighboring electrically conductive layer 46 by a second lateral protrusion distance lpd2; and the second lateral protrusion distance lpd2 is the same as the first lateral protrusion distance lpd1.

In one embodiment illustrated in FIG. 14C, the respective tab portion 46T laterally protrudes away from the memory array region 100 relative to a respective first additional electrically conductive layer 46 that underlies the respective underlying vertically-neighboring electrically conductive layer 46, and relative to a respective second additional electrically conductive layer 46 that overlies the respective overlying vertically-neighboring electrically conductive layer 46. In one embodiment, a sidewall of the respective first additional electrically conductive layer 46, a sidewall of the respective underlying vertically-neighboring electrically conductive layer 46, a sidewall of the respective second additional electrically conductive layer 46, and a sidewall of the respective overlying vertically-neighboring electrically conductive layer 46 are vertically coincident with each other.

In one embodiment, the finned dielectric material portion 65 includes laterally-extending dielectric fins 65F that extend into gaps between a neighboring pair of the insulating layers 32. In one embodiment, a tab portion 46T of the tab portions 46T of the subset of the electrically conductive layers 46 is vertically spaced from a most proximal overlying one of the laterally-extending dielectric fins 65F by one of the insulating layers 32, and is vertically spaced from a most proximal underlying one of the laterally-extending dielectric fins 65F by another of the insulating layers 32.

In one embodiment, the tab portion 46T of the tab portions of the subset of the electrically conductive layers 46 has an areal overlap with two overlying laterally-extending dielectric fins 65F and has an areal overlap with two underlying laterally-extending dielectric fins 65F. In one embodiment, the tab portion 46T of the tab portions of the subset of the electrically conductive layers 46 is laterally spaced from the finned dielectric material portion 65 by an etch-stop material portion 22; the etch-stop material portion 22 has a vertical extent that is less than a sum of twice a thickness of an insulating layer 32 of the insulating layers 32 and three times a thickness of an electrically conductive layer 46 of the electrically conductive layers 46; and the etch-stop material portion 22 has a top surface, a bottom surface, and a sidewall that contacts the finned dielectric material portion 65.

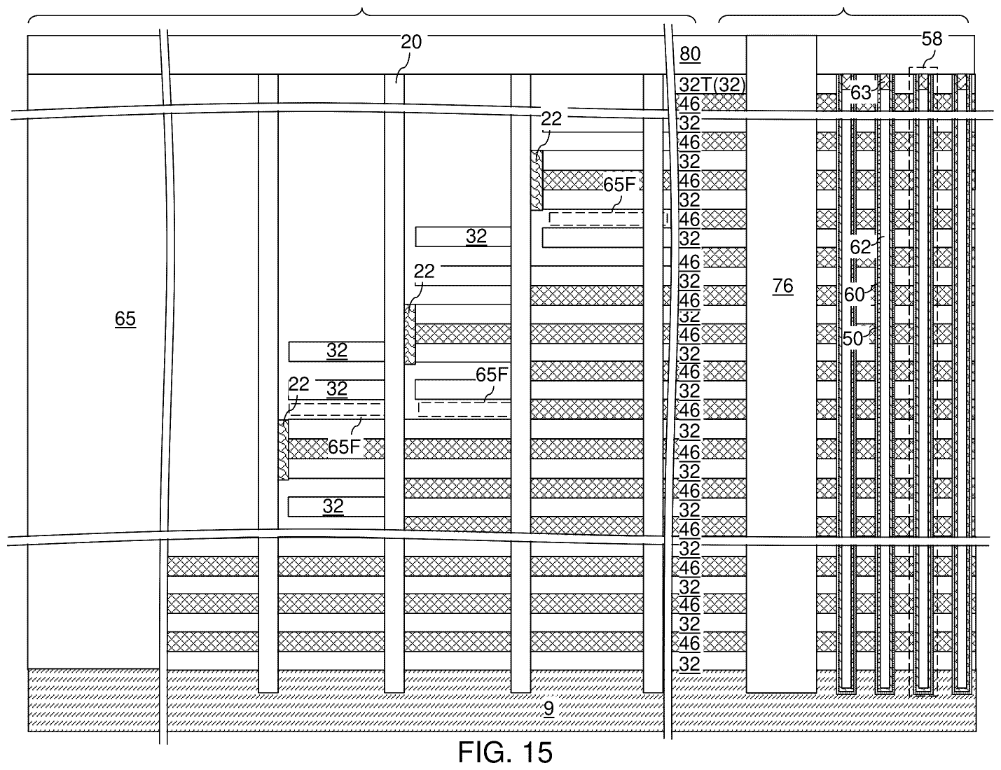

Referring to FIG. 15, a dielectric fill material, such as silicon oxide can be deposited in the lateral isolation trenches 79. Excess portions of the dielectric fill material can be removed from above the contact-level dielectric layer 80. Each remaining portion of the dielectric fill material that fills a respective one of the lateral isolation trenches 79 constitutes a lateral isolation trench fill structure 76, which may be a dielectric wall structure. In an alternative embodiment, an insulating spacer having a tubular configuration can be formed in peripheral portions of each of the lateral isolation trenches 79, and a through-stack conductive via structure may be formed within a respective one of the insulating spacers. In this case, each lateral isolation trench fill structure 76 may comprise a combination of a through-stack conductive via structure and an insulating spacer that laterally surrounds the through-stack conductive via structure.

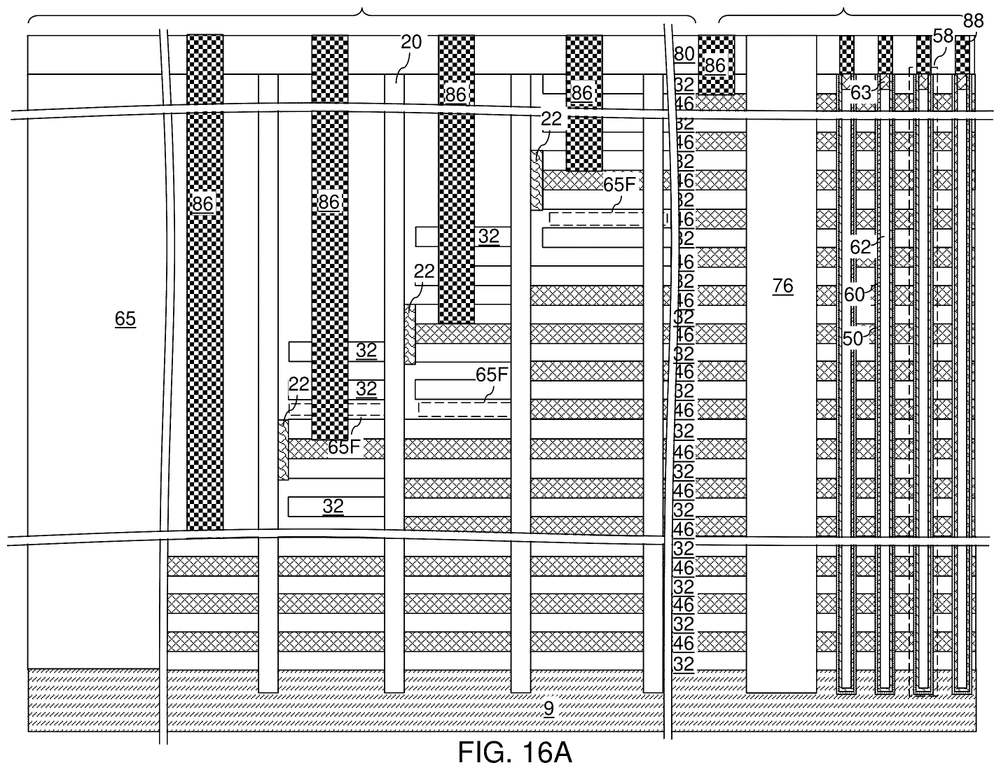

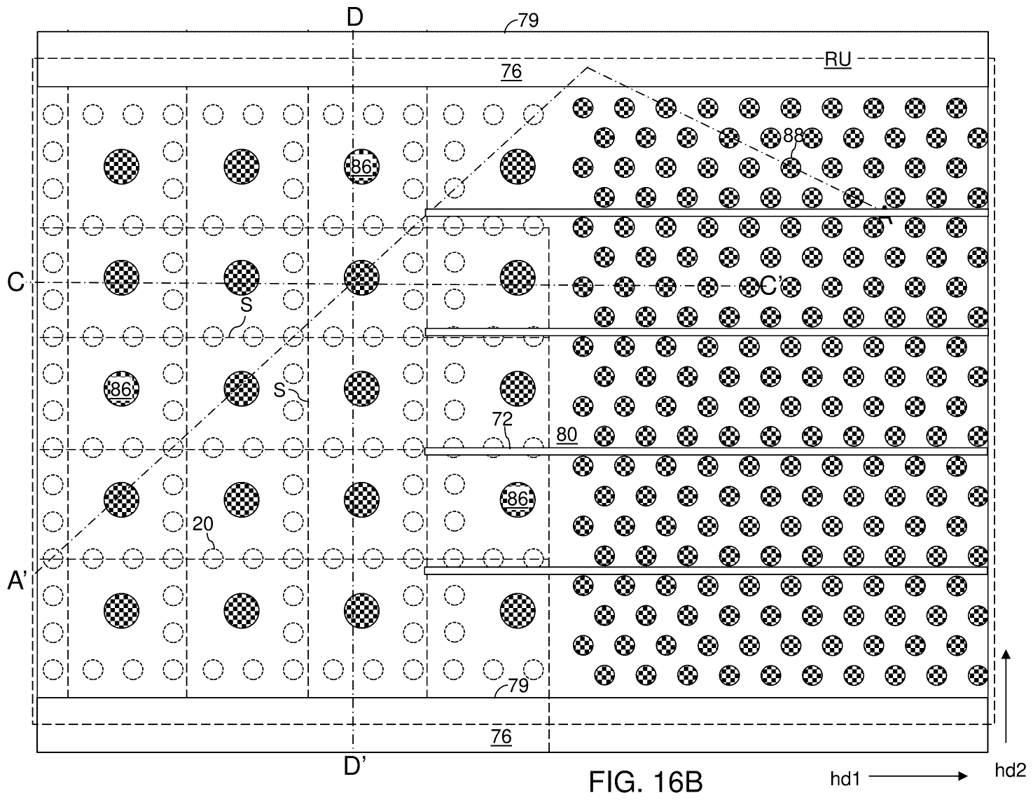

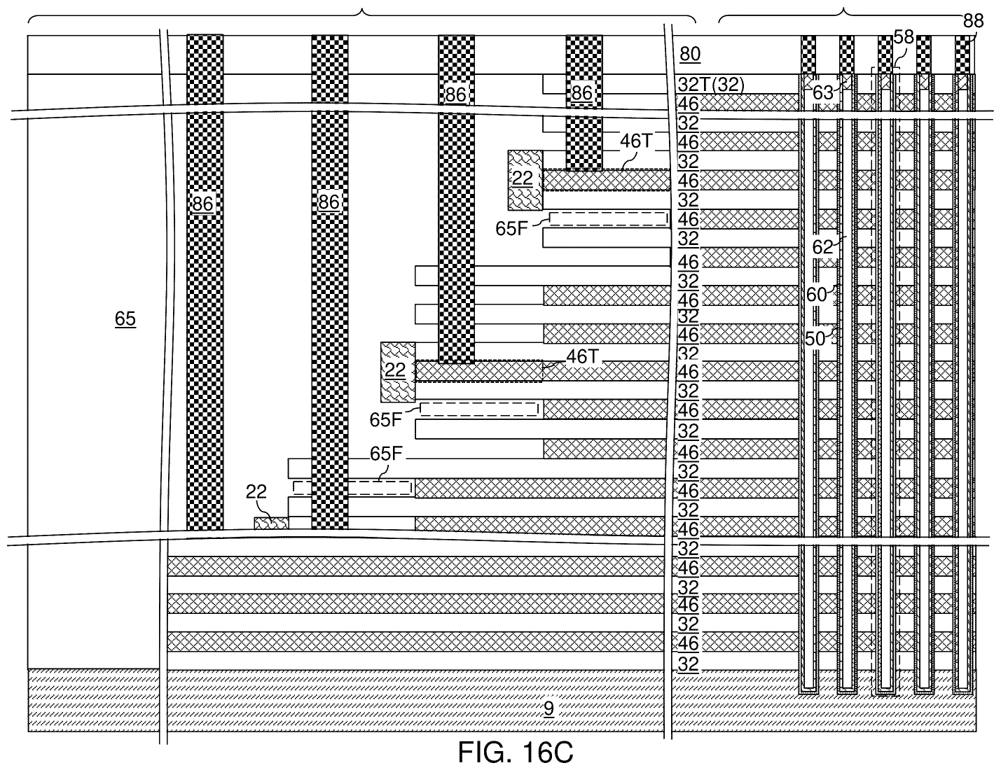

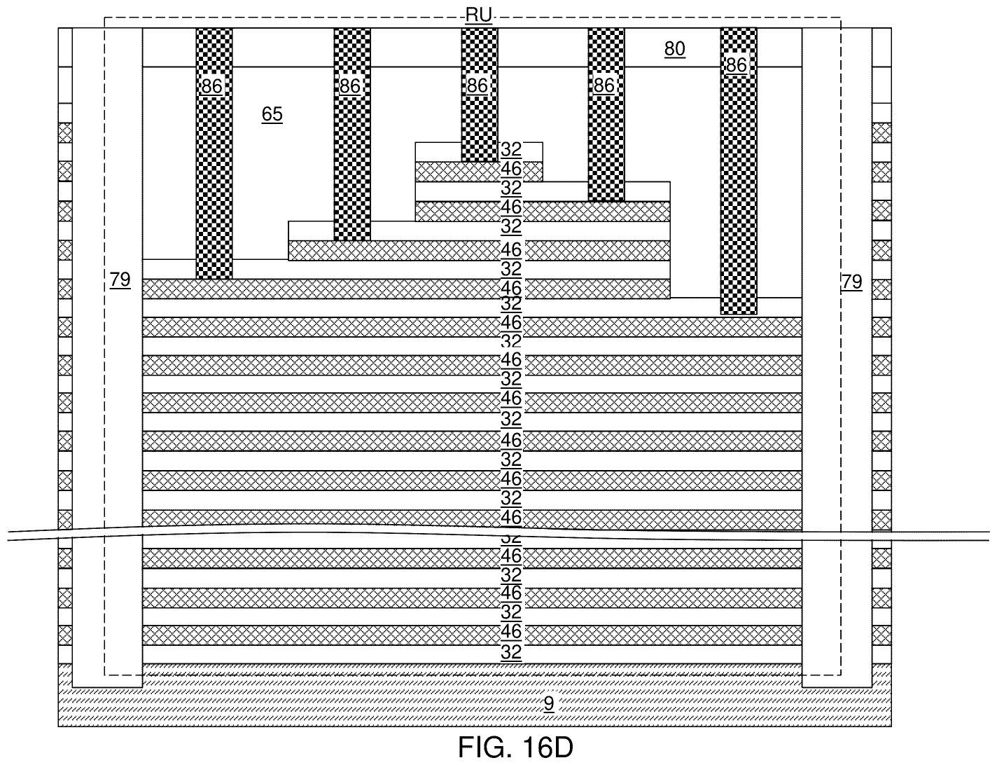

Referring to FIGS. 16A-16D, contact via structures (88, 86) can be formed through the contact-level dielectric layer 80, and optionally through the finned dielectric material portion 65. For example, drain contact via structures 88 can be formed through the contact-level dielectric layer 80 on each drain region 63. Layer contact via structures 86 can be formed on the electrically conductive layers 46 through the contact-level dielectric layer 80, and through the finned dielectric material portion 65.

As shown in FIG. 16C, the layer contact via structures 86 can contact the respective tab portion 46T of the respective electrically conductive layer 46 in a tab region of the electrically conductive layer 46, which is vertically spaced from underlying electrically conductive layers 46 by a vertical distance that is at least the sum of twice the thickness of an insulating layer 32 and a thickness of a dielectric fin 65F. Leakage current between a vertically neighboring pair of electrically conductive layers 46 can be reduced because the increase in the vertical distance between the tab portion of an electrically conductive layer 46 and an underlying electrically conductive layer 46 having an areal overlap with the tab portion reduces the probability of vertical extension of a layer contact via structure through the electrically conductive layer 46 and toward the underlying electrically conductive layer 46. By increasing the vertical spacing between the tab portion of each electrically conductive layer 46 and an underlying electrically conductive layer 46, the probability of electrical shorts between electrically conductive layers 46 is also reduced.

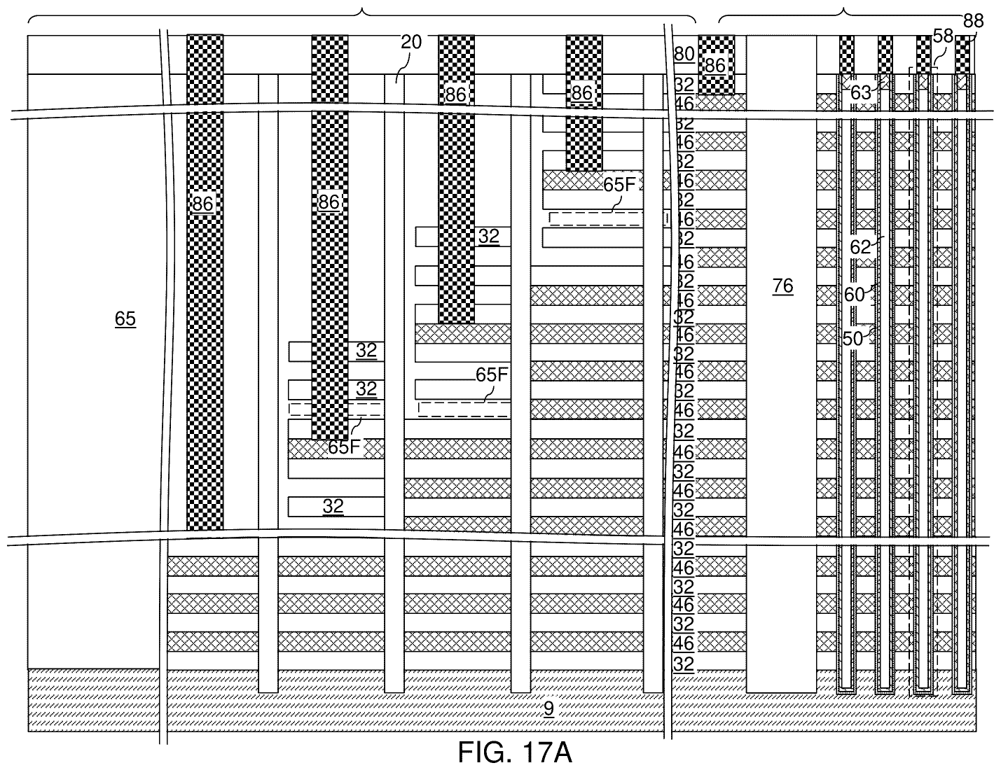

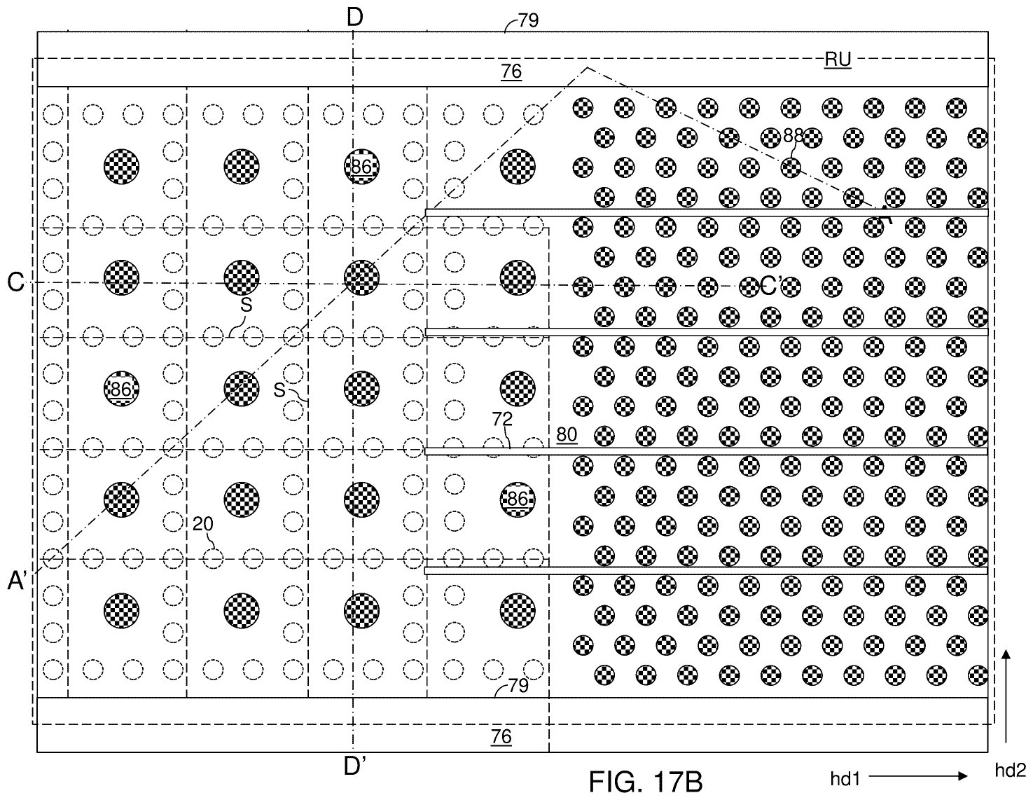

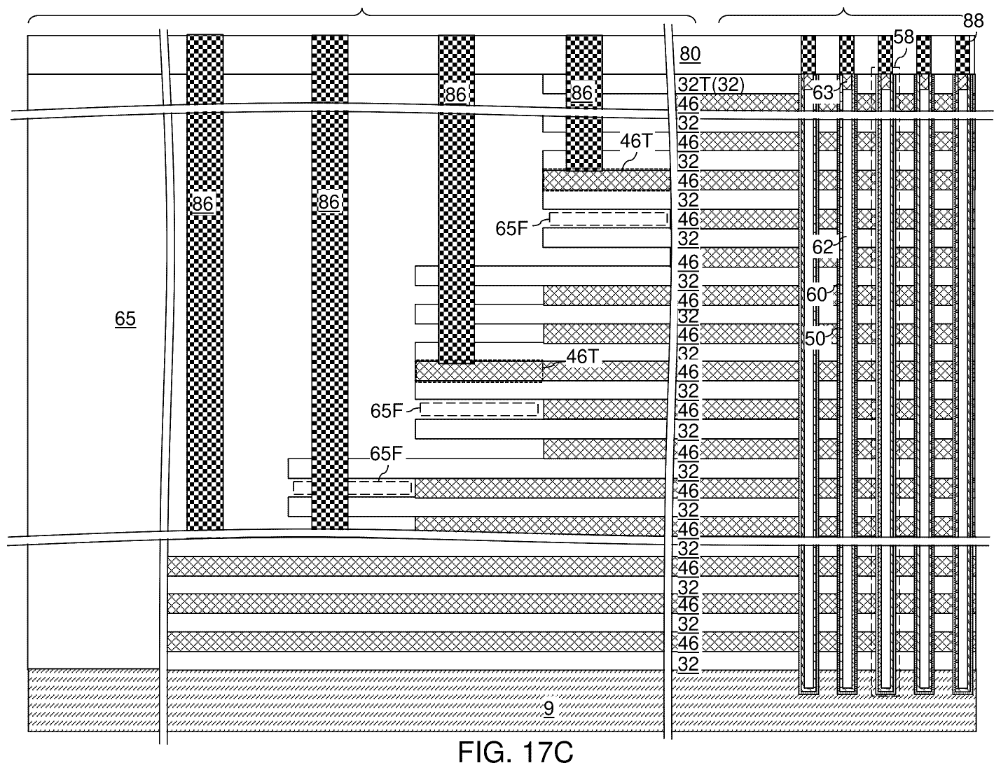

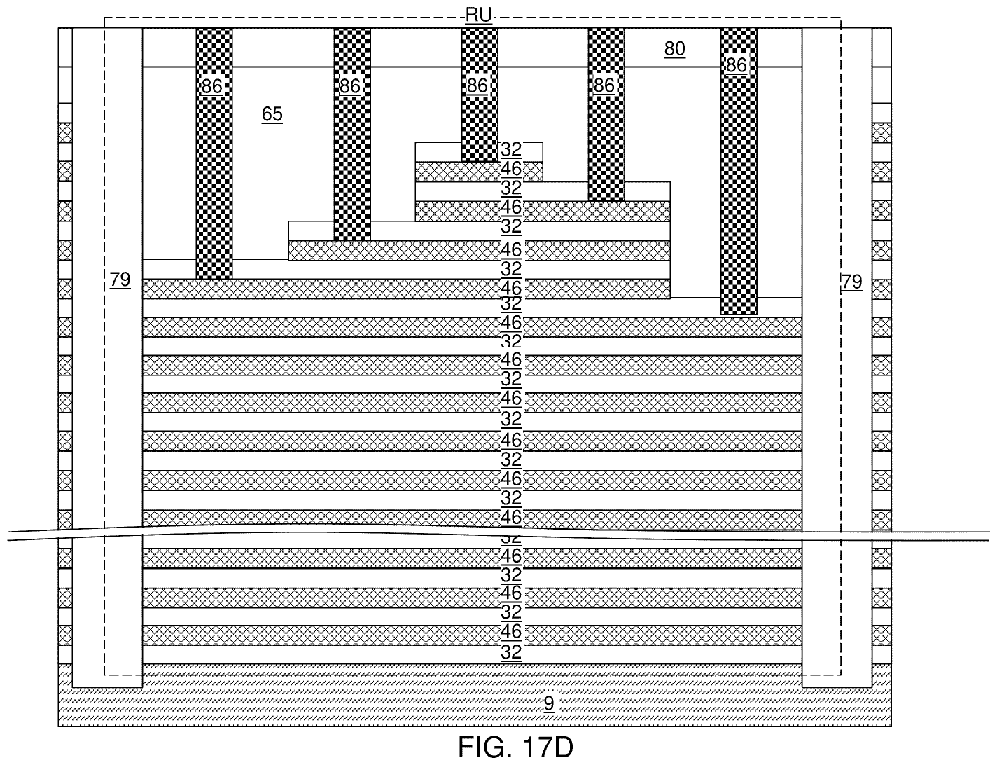

Referring to FIGS. 17A-17D, an alternative configuration of the exemplary structure is illustrated at a processing step that corresponds to the processing steps of FIGS. 16A-16D. The alternative configuration of the exemplary structure can be derived from the exemplary structure of FIGS. 16A-16D by removing the etch-stop material portions 22 at the processing steps described with reference to FIGS. 3F and 4.

Referring collectively to FIGS. 16A-16D and 17A-17D and according to an aspect of the present disclosure, a subset of the layer contact via structures 86 contacts a top surface of a respective one of the tab portions of the electrically conductive layers 46. In one embodiment, a subset of the layer contact via structures 86 vertically extends through, and contacts, a respective set of at least two insulating layers 32 that overlies an electrically conductive layer that is contacted by a respective layer contact via structure 86. In one embodiment, for each layer contact via structure 86 that contacts a tab portion of an electrically conductive layer 46, the layer contact via structure 86 contacts, and vertically extends through, a respective set of at least two insulating layers 32 that overlie the electrically conductive layer 46. In the illustrated example in FIGS. 16A-16D, for each layer contact via structure 86 that contacts a tab portion of an electrically conductive layer 46, the layer contact via structure 86 contacts, and vertically extends through, a respective set of three insulating layers 32 that overlie the electrically conductive layer 46.

In one embodiment, for each layer contact via structure 86 that contacts a tab portion 46T of an electrically conductive layer 46, the layer contact via structure 86 contacts, and vertically extends through, a respective set of at least one dielectric fin 65F that overlies and has an areal overlap in a plan view with, the tab portion 46T of the electrically conductive layer 46. In the illustrated example in FIGS. 16A-16D, for each layer contact via structure 86 that contacts a tab portion of an electrically conductive layer 46, the layer contact via structure 86 contacts and vertically extends through, a respective set of two dielectric fin 65F that overlie and have an areal overlap in a plan view with the tab portion 46T of the electrically conductive layer 46.

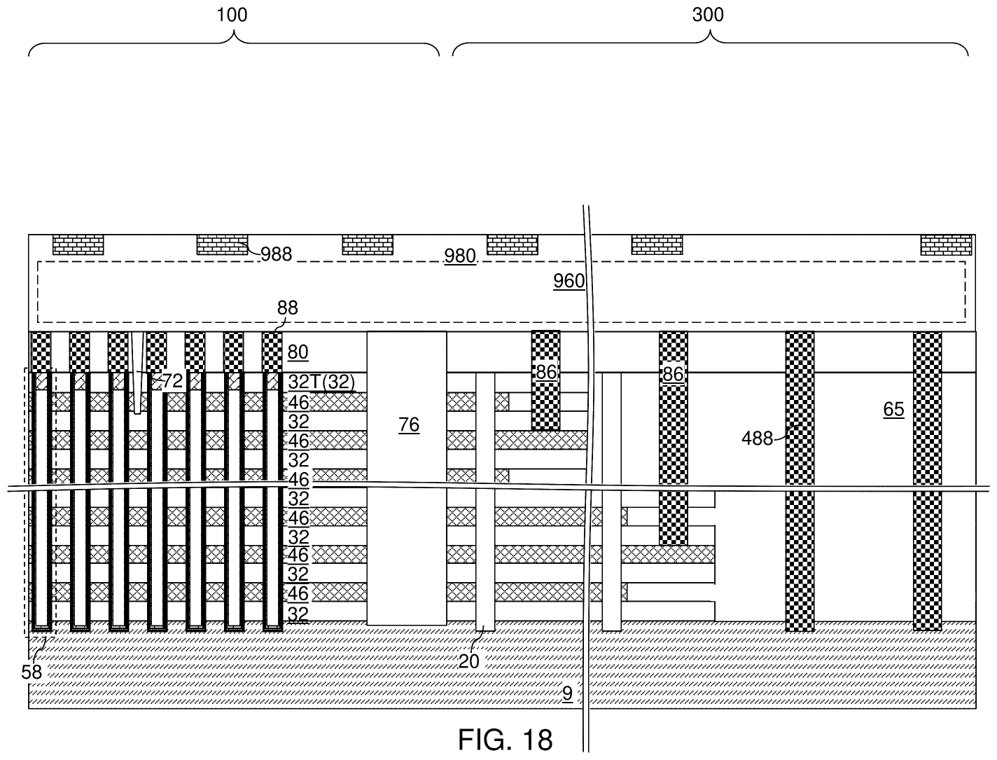

Referring to FIG. 18, additional dielectric material layers and additional metal interconnect structures can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; and a two-dimensional array of contact via structures (such as the drain contact via structures 88) overlying the three-dimensional memory array and electrically connected to a respective one of the vertical semiconductor channels 60.

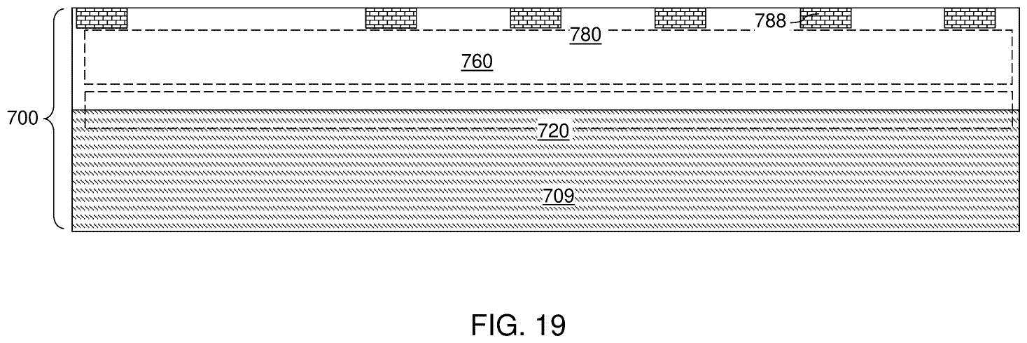

Referring to FIG. 19, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 788. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900.

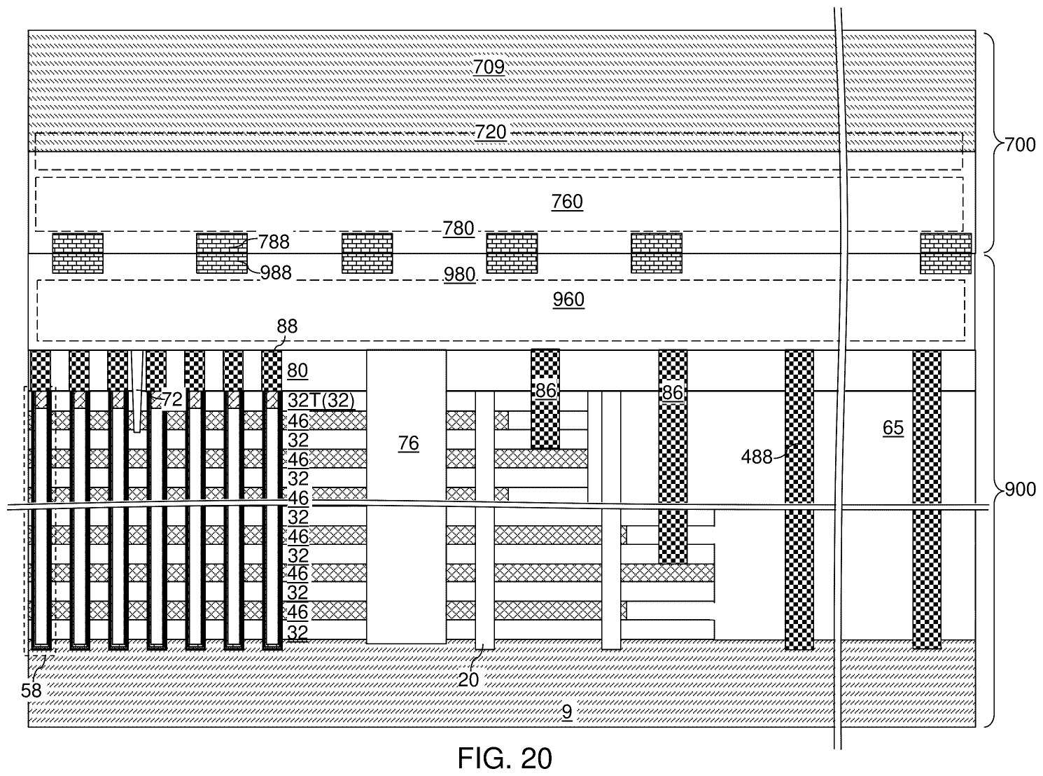

Referring to FIG. 20, the logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

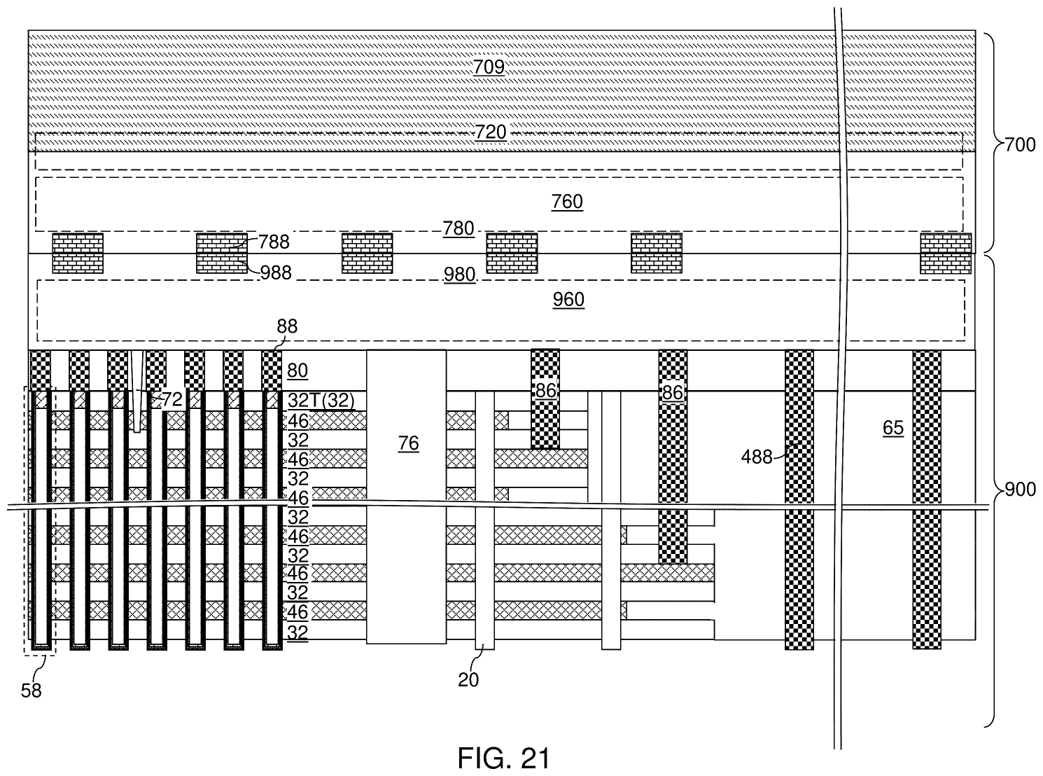

Referring to FIG. 21, the carrier substrate 9 can be removed, for example, by grinding, polishing, cleaving, an isotropic etch process, an anisotropic etch process, and/or a combination thereof. If a chemical mechanical polishing process or an etch process is employed as a terminal step for removing the carrier substrate 9, the bottommost insulating layer 32B may be employed as a polish stop or etch stop, respectively.

In one embodiment, at least a terminal step of at least one removal process that is employed to remove the carrier substrate 9 may comprise a selective wet etch process that etches the material of the carrier substrate 9 (such as a semiconductor material of the carrier substrate 9) selective to dielectric materials of the memory films 50. In an illustrative example, if the carrier substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the carrier substrate 9 can be removed by the selective wet etch process. Backside end surfaces of the support pillar structures 20 can be physically exposed upon removal of the carrier substrate 9.

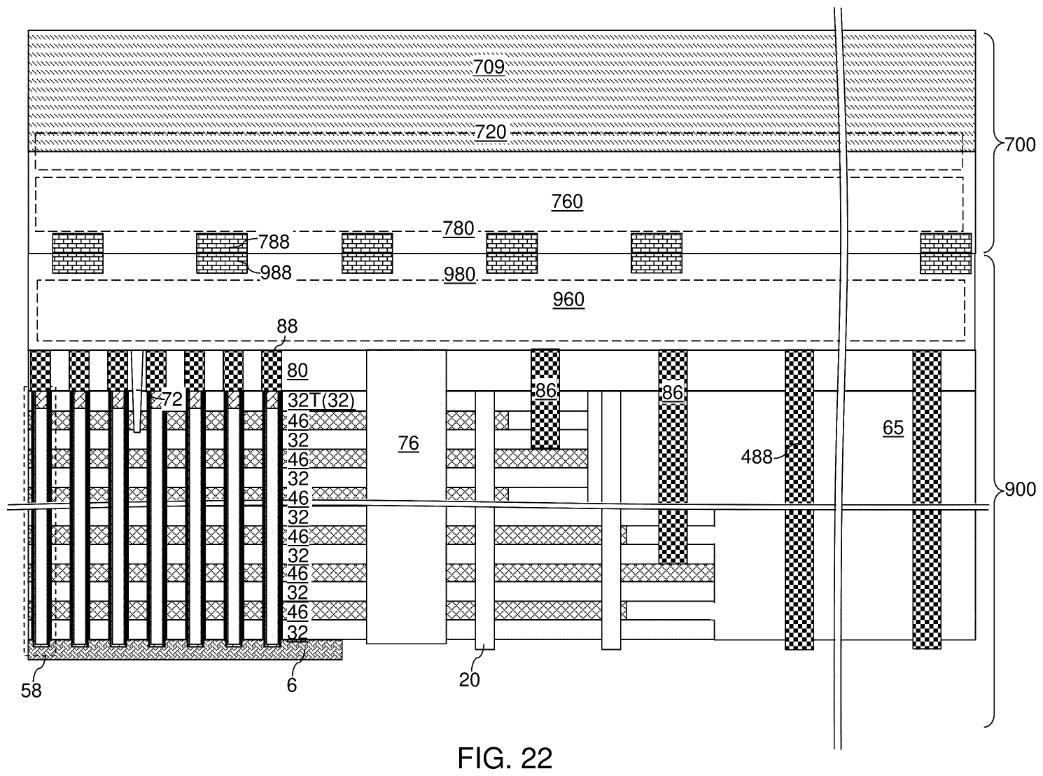

Referring to FIG. 22, an end portion of each memory film 50 may be removed by performing a sequence of wet etch processes. In one embodiment, the sequence of wet etch processes may comprise a first wet etch process that etches the material of the blocking dielectric layer 52 selective to the material of the memory material layer 54, a second wet etch process that etches the material of the memory material layer 54 selective to the material of the dielectric liner 56, and a third wet etch process that etches the material of the dielectric liner 56 selective to the material of the vertical semiconductor channel 60. Upon removal of the end portion of the memory film 50, an end portion of each vertical semiconductor channel 60 may be physically exposed.

A source material layer can be deposited on the physically exposed end surfaces of the vertical semiconductor channels 60, and can be subsequently patterned to form a source layer 6. The source material may comprise a heavily doped semiconductor material and/or at least one metallic material.

Subsequently, backside insulating layers (not shown) can be deposited over the source layer 6, and various connection via structures (not shown) and backside contact pad structures (not shown) can be formed through the backside insulating layer.

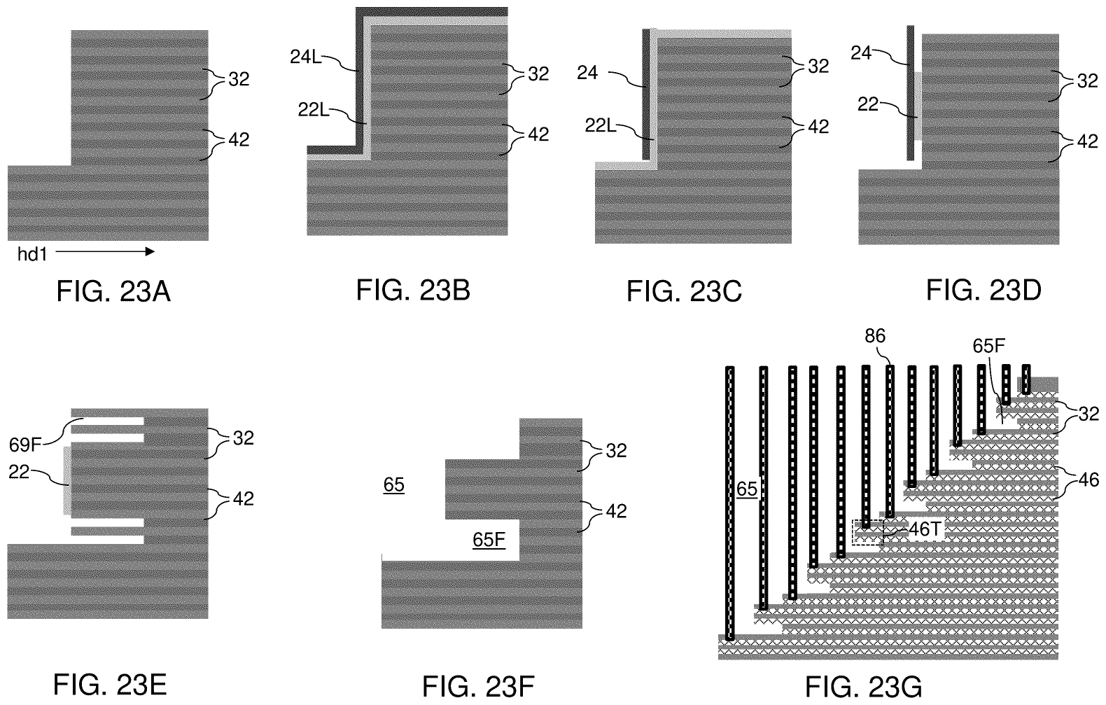

FIGS. 23A-23G illustrate steps in method of forming a second exemplary structure of an alternative embodiment of the present disclosure. The second exemplary structure of FIG. 23A may be identical to the first exemplary structure of FIG. 3A.

Referring to FIG. 23B, the steps described above with reference to FIG. 3B may then be performed to deposit the barrier material layer 24L and the etch-stop material layer 22L.

Referring to FIG. 23C, the step described above with reference to FIG. 3C may then be performed to form the barrier walls 24.

Referring to FIG. 23D, the step described above with reference to FIG. 3D may then be performed to form the etch-stop material portions 22 with the modification that the etch-stop material portions 22 in the second exemplary structure of FIG. 23D are taller than in the first exemplary structure of FIG. 3D. Specifically, the duration of the selective etch process during in the alternative embodiment is shorter than in the first embodiment, such that each of the etch-stop material portions 22 covers the sidewalls of more than one respective sacrificial material layer 42. For example, as shown in FIG. 23, the etch-stop material portion 22 covers the sidewalls of four vertically adjacent sacrificial material layers 42. In general, the etch-stop material portions 22 may cover the sidewalls of two to ten vertically adjacent (i.e., vertically sequential) sacrificial material layers 42.

Referring to FIG. 23E, the step described above with reference to FIG. 3E may then be performed to form to form the fin cavities 69F. More than two sacrificial material layers 42 are located between two vertically adjacent fin cavities 69F in the alternative embodiment.

Referring to FIG. 23F, the steps described above with reference to FIG. 3F may be optionally performed to selectively remove the etch-stop material portions 22 and to form the laterally-extending dielectric fins 65F.

Referring to FIG. 23G, the steps described above with reference to FIGS. 5A to 17D may be performed to form the electrically conductive layers 46 and the layer contact via structures 86. In the alternative embodiment, more than one (e.g., two to ten) vertically adjacent (i.e., vertically sequential) electrically conductive layers 46 include tab portions 46T having sidewalls that are vertically coincident with each other.

Thus, in the alternative embodiment, at least one of the respective underlying vertically-neighboring electrically conductive layer 46 and the respective overlying vertically-neighboring electrically conductive layer 46 are not vertically adjacent to the electrically conductive layer 46 that comprises the respective tab portion 46T; and at least two of the vertically adjacent electrically conductive layers 46 in the subset of the electrically conductive layers comprise the respective tab portions 46T that have vertically coincident sidewalls.

The process of the alternative embodiment uses less photolithographic masking steps and reactive ion etching steps to form the staircase(s) in the contact region than a process in which the tab portions 46T and the laterally-extending dielectric fins 65F are not included.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device, comprising:
an alternating stack of insulating layers and electrically conductive layers that alternate along a vertical direction;
memory openings vertically extending through the alternating stack in a memory array region;
memory opening fill structures located in the memory openings and comprising a respective vertical stack of memory elements and a respective vertical semiconductor channel; and
layer contact via structures contacting the electrically conductive layers;
wherein:
each electrically conductive layer within a subset of the electrically conductive layers comprises a respective tab portion that laterally protrudes away from the memory array region relative to a respective underlying vertically-neighboring electrically conductive layer and relative to a respective overlying vertically-neighboring electrically conductive layer; and
a subset of the layer contact via structures contacts a top surface of a respective one of the tab portions.

2. The memory device of claim 1, wherein:
each layer within the alternating stack laterally extends along a first horizontal direction and has a uniform layer stack width along a second horizontal direction in the memory array region;
the tab portions of the subset of the electrically conductive layers laterally protrude along the first horizontal direction; and
the tab portions have a respective tab width that is less than the uniform layer stack width.

3. The memory device of claim 2, wherein:
each electrically conductive layer within the subset of the electrically conductive layers is located between a respective vertically-neighboring pair of insulating layers of the insulating layers; and
the respective vertically-neighboring pair of insulating layers have sidewalls that laterally extend along the second horizontal direction and are vertically coincident with each other.

4. The memory device of claim 3, wherein each electrically conductive layer within the subset of the electrically conductive layers is in direct contact with the respective vertically-neighboring pair of insulating layers, and has a respective sidewall that is vertically coincident with the sidewalls of the respective vertically-neighboring pair of insulating layers.

5. The memory device of claim 4, wherein each electrically conductive layer within the subset of the electrically conductive layers is spaced from the respective vertically-neighboring pair of insulating layers by a respective outer blocking dielectric layer, and has a respective sidewall that is laterally offset from the sidewalls of the respective vertically-neighboring pair of insulating layers by a thickness of the respective outer blocking dielectric layer.

6. The memory device of claim 4, wherein a respective first additional insulating layer that underlies the respective vertically-neighboring pair of insulating layers and a respective second additional insulating layer that overlies the respective vertically-neighboring pair of insulating layers have sidewalls that laterally extend along the second horizontal direction and are vertically coincident with the sidewalls of the respective vertically-neighboring pair of insulating layers.

7. The memory device of claim 1, wherein the respective underlying vertically-neighboring electrically conductive layer and the respective overlying vertically-neighboring electrically conductive layer are vertically adjacent to the electrically conductive layer that comprises the respective tab portion.

8. The memory device of claim 1, wherein:
at least one of the respective underlying vertically-neighboring electrically conductive layer and the respective overlying vertically-neighboring electrically conductive layer are not vertically adjacent to the electrically conductive layer that comprises the respective tab portion; and
at least two of the vertically adjacent electrically conductive layers in the subset of the electrically conductive layers comprise the respective tab portions that have vertically coincident sidewalls.

9. The memory device of claim 1, wherein:
the respective tab portion laterally protrudes away from the memory array region relative to the respective underlying vertically-neighboring electrically conductive layer by a first lateral protrusion distance;
the respective tab portion laterally protrudes away from the memory array region relative to the respective overlying vertically-neighboring electrically conductive layer by a second lateral protrusion distance; and
the second lateral protrusion distance is the same as the first lateral protrusion distance.

10. The memory device of claim 1, wherein:
the respective tab portion laterally protrudes away from the memory array region relative to a respective first additional electrically conductive layer that underlies the respective underlying vertically-neighboring electrically conductive layer, and relative to a respective second additional electrically conductive layer that overlies the respective overlying vertically-neighboring electrically conductive layer; and
a sidewall of the respective first additional electrically conductive layer, a sidewall of the respective underlying vertically-neighboring electrically conductive layer, a sidewall of the respective second additional electrically conductive layer, and a sidewall of the respective overlying vertically-neighboring electrically conductive layer are vertically coincident with each other.

11. The memory device of claim 1, further comprising a finned dielectric material portion that includes laterally-extending dielectric fins that extend into gaps between neighboring pair of insulating layers of the insulating layers.

12. The memory device of claim 11, wherein a tab portion of the tab portions of the subset of the electrically conductive layers is vertically spaced from a most proximal overlying one of the laterally-extending dielectric fins by at least one of the insulating layers, and is vertically spaced from a most proximal underlying one of the laterally-extending dielectric fins by at one other one of the insulating layers.

13. The memory device of claim 12, wherein a tab portion of the tab portions of the subset of the electrically conductive layers has an areal overlap with at least one of the overlying laterally-extending dielectric fins and has an areal overlap with at least one of the underlying laterally-extending dielectric fins.

14. The memory device of claim 12, wherein:
a tab portion of the tab portions of the subset of the electrically conductive layers is laterally spaced from the finned dielectric material portion by an etch-stop material portion; and
the etch-stop material portion has a top surface, a bottom surface, and a sidewall that contacts the finned dielectric material portion.

15. A method of forming a memory device, comprising:
forming an alternating stack of insulating layers and sacrificial material layers over a substrate;
forming stepped surfaces by patterning the alternating stack, wherein the stepped surfaces comprise horizontally-extending surfaces and vertically-extending surfaces;
forming etch-stop material portions on the vertically-extending surfaces, wherein first vertically-extending surface segments of the vertically extending surfaces are laterally covered by the etch-stop material portions and second vertically-extending surface segments of the vertically-extending surfaces are not laterally covered by the etch-stop material portions;
isotropically recessing portions of the sacrificial material layers having sidewalls at the second vertically-extending surface segments without laterally recessing portions of the sacrificial material layers having sidewalls at the first vertically-extending surface segments, such that fin cavities are formed in volumes from which a material of the sacrificial material layers is removed;
forming a dielectric material portion over the stepped surfaces, wherein the finned dielectric material portion comprises laterally-extending dielectric fins that fill the fin cavities;
forming memory openings through the alternating stack;
forming memory opening fill structures in the memory openings, wherein each of the memory opening fill structures comprises a respective vertical stack of memory elements and a vertical semiconductor channel; and
replacing the sacrificial material layers with electrically conductive layers.

16. The method of claim 15, wherein a subset of the electrically conductive layers comprise a respective tab portion that overlies and has an areal overlap in a plan view with a respective underlying laterally-extending dielectric fin.

17. The method of claim 16, wherein the respective tab portion underlies and has an areal overlap in the plan view with a respective overlying laterally-extending dielectric fin.

18. The method of claim 15, further comprising forming layer contact via structures through the finned dielectric material portions, wherein one of the layer contact via structures vertically extends through a laterally-extending dielectric fin and through a portion of the finned dielectric material portion that overlies the laterally-extending dielectric fin.

19. The method of claim 18, wherein said one of the layer contact via structures vertically extends through two or more insulating layers of the insulating layers and contacts a respective one of the tab portions.

20. The method of claim 15, further comprising:
forming an etch-stop material layer and a barrier material layer over the stepped surfaces;
removing horizontally-extending portions of the barrier material layer by performing an anisotropic etch process, wherein remaining vertically-extending portions of the barrier material layer comprise barrier walls; and
isotropically etching the etch-stop material layer employing an etch chemistry that etches a material of the etch-stop material layer selective to the barrier walls, wherein remaining portions of the etch-stop material layer comprise the etch-stop material portions.
